(19) United States
(12) Patent Application Publication
(10) Pub. No.: US 2013/0320326 A1
(43) Pub. Date: Dec. 5, 2013

(54) INSULATING MATERIAL FORMING COMPOSITION FOR ELECTRONIC DEVICES, INSULATING MATERIAL FOR ELECTRONIC DEVICES, ELECTRONIC DEVICES AND THIN FILM TRANSISTOR

(71) Applicants: Naoki Kurihara, Sodegaura-shi (JP); Masatoshi Saito, Sodegaura-shi (JP)

(72) Inventors: Naoki Kurihara, Sodegaura-shi (JP); Masatoshi Saito, Sodegaura-shi (JP)

(73) Assignee: Idemitsu Kosan Co., Ltd.

(21) Appl. No.: 14/000,118

(22) PCT Filed: Feb. 14, 2012
(86) PCT No.: PCT/JP2012/000961

§ 371 Date: Aug. 16, 2013

(30) Foreign Application Priority Data
Feb. 18, 2011 (JP) 2011-033107

(51) Int. Cl. H01B 3/44; H01L 29/40

(52) U.S. Cl. CPC H01B 3/447; H01L 29/408
USPC 257/40; 257/410; 526/281; 526/247; 526/283; 526/261; 560/194

(57) ABSTRACT

A composition for forming an insulating material used in electronic devices which includes, as a polymerizable component, a monomer comprising two or more (meth)acrylic moieties and a polycyclic alicyclic structure.

### TECHNICAL FIELD

The invention relates to an insulating material forming composition for electronic devices and electronic devices using the same.

### BACKGROUND ART

In an electronic element having a switching function such as a thin film transistor (TFT), an organic electroluminescence (EL) device and a liquid crystal cell, an insulating material used to insulate between layers is an essential material.

A thin film transistor which is a representative electronic device has widely been used as a switching element of a display device such as a liquid crystal display device or an organic EL display device.

This TFT has hitherto been produced by using amorphous or polycrystalline silicon. However, a CVD (Chemical Vapor Deposition) device used for fabricating a TFT using silicon is very expensive. Therefore, an increase in size of a display device or the like using a TFT has a problem that it leads to a significant increase in production cost. Further, since forming amorphous or polycrystalline silicon into a film is conducted at significantly high temperatures, the type of a material usable as a substrate is limited, making use of a lightweight resin substrate or the like impossible.

In order to solve the above-mentioned problem, a TFT using an organic substance instead of amorphous silicon and polycrystalline silicon has been proposed. As the method for forming a TFT using an organic substance, a vacuum vapor deposition method or a coating method is known to be usable. In particular, by using a coating method, it is possible to realize an increase in size of an apparatus using a TFT while suppressing an increase in production cost. It is also possible to allow the process temperature which is required during film-formation to be relatively low. Therefore, a TFT using an organic substance has an advantage that only small restrictions are imposed on the material which can be used in a substrate.

Reports on TFTs using an organic substance have been actively made (Non-Patent Documents 1 and 2, for example), and its practical use has been expected.

A wide variety of materials have been studied for a gate insulator layer used in a TFT (hereinafter, often referred to as the “gate insulating film”). A polymeric insulator is introduced as an insulating material for a TFT which can be formed into a film easily by spin coating or the like and can exhibit excellent properties (Non-Patent Document 2).

However, a polymeric insulator which has conventionally been known has a room of improvement. First, the type of a polymeric insulator which can be formed into a film by coating is limited. Even in the case of a polymeric insulator which can be formed into a film by coating, the polymeric insulator cannot often withstand conditions under which subsequent coating steps, such as formation of a semiconductor layer in a bottom-gate TFT, formation of a conductor layer such as an electrode, formation of a protective layer after fabrication of a TFT, or the like), are conducted (the type of a solvent used, for example), thereby making device fabrication impossible.

Secondary, many of polymeric insulators have low heat resistance. In particular, an acrylic polymeric insulating film represented by poly(methyl methacrylate) (PMMA) cannot often withstand process temperatures of post treatments after the formation of a TFT, such as process temperatures used during the formation of an organic EL device after the formation of a TFT, in the formation of an organic EL display apparatus.

Thirdly, since the leakage current density of a conventional polymeric insulator is relatively high (normally, higher than 1×10⁻⁷ A/cm² at 2 MV/cm), favorable TFT properties cannot be obtained.

Therefore, as a composition for forming an insulating material used in electronic devices, a cross-linkable polymeric insulating material which can be formed into a film by a solution method and can withstand coating process subsequent to the formation of a coating film has been required. Further, a composition for forming an insulating material used in electronic devices is required to have heat resistance and have a low leakage current density.

Patent Document 1 discloses an adamantane derivative having a specific structure. However, no attention is made to the leakage current density, and no reference is made to the application in which a low leakage current density is essential.

By the use of a polymeric gate insulating film in which a polymer having a specific hydrophobic main chain such as poly(methyl methacrylate) (PMMA) is incorporated, there is a possibility that a low TFT gate leakage current density is attained (Non-Patent Document 3). However, it lacks cross-linking functionality, and hence, when other layers are formed by a solution process after the film formation, the film may be dissolved or the like in the subsequent film-formation processes. Therefore, there is a possibility that this film cannot withstand the device fabrication.

As a means for solving these problems, a cross-linkable polymeric insulator as disclosed in Patent Documents 2 and 3 and Non-Patent Document 4 has been reported. However, no disclosure is made on the monomer structure of the invention.

### RELATED ART DOCUMENTS

### Patent Documents

Patent Document 1: JP-A-2008-105999
Patent Document 2: JP-T-2010-511094
Patent Document 3: JP-A-2006-28497

### Non-Patent Documents

Non-Patent Document 1: C. Dimitrakopoulos, et al., Advanced Materials Vol. 14, page 99, 2002
Non-Patent Document 2: A. Facchetti, et al., Advanced Materials Vol. 17, page 1705, 2005
Non-Patent Document 3: C. Kim et al., Science Vol. 318, pages 76-80, 2007
Non-Patent Document 4: H. Klauk et al., Journal of Applied Physics Vol. 92, page 5259, 2002

### SUMMARY OF THE INVENTION

An object of the invention is to provide a composition for forming an insulating material used in electronic devices which can be formed into a film by a solution method and, if other layers are formed by a coating process after the formation of a coating film, can withstand the steps of the coating process, has heat resistance and has a low leakage current density, as well as to provide an electronic device exhibiting excellent properties by using the composition. As such an electronic device, a TFT and an apparatus provided with a TFT can be given. As such an apparatus (electronic device), a display device such as a liquid crystal display device or an organic EL display device can be given, for example.

The inventors made intensive studies in order to solve the above-mentioned problems, and found that a composition for forming a material used in an electronic device comprising as a polymer component, a monomer that has two or more (meth)acrylic moieties and a polycyclic alicyclic structure and an electronic device comprising an insulating material obtained by curing this composition can solve the above-mentioned problems. The invention has been made based on this finding.

According to the invention, the following composition for forming an insulating material used in electronic devices, insulating material for electronic devices, an electronic device, and thin film transistor are provided.

1. A composition for forming an insulating material used in electronic devices which comprises, as a polymerizable component, a monomer comprising two or more (meth)acrylic moieties and a polycyclic alicyclic structure.
2. The composition for forming an insulating material used in electronic devices according to 1, wherein the polycyclic alicyclic structure is an adamantane skeleton.
3. The composition for forming an insulating material used in electronic devices according to 1, wherein the polycyclic alicyclic structure is a tricyclo[5.2.1.0^{2,6}]decane skeleton.
4. The composition for forming an insulating material used in electronic devices according to 2, wherein the structure of the monomer is represented by the following formula (I) or (II):

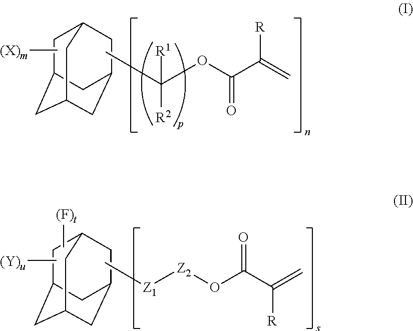

wherein R is a hydrogen atom, a fluorine atom, a methyl group or a trifluoromethyl group, X is a fluorine atom, a methyl group, a trifluoromethyl group or ═O formed by combination of two Xs; and Y is a methyl group or ═O formed by combination of two Ys; R¹ and R² are independently a hydrogen atom, a halogen atom or an alkyl group having 1 to 5 carbon atoms;

p is an integer of 0 to 6; m is an integer of 0 to 14; n is an integer of 2 or more; t is an integer of 0 to 14; u is an integer of 0 to 14; and s is an integer of 2 or more; and plural Xs and plural Ys may be the same or different from each other;

Z₁ is a group represented by —C_{(q+r)}F_{2q}H₂ᵣ— (q is an integer of 0 to 4 and r is an integer of 0 to 4); and Z₂ is a single bond or a group represented by the following formula (II-1) or (II-2):

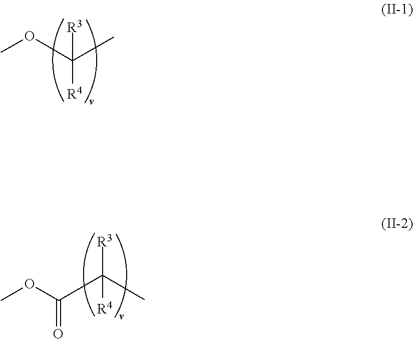

wherein R³ and R⁴ are independently a hydrogen atom, a halogen atom or an alkyl group having 1 to 5 carbon atoms; and v is an integer of 1 to 4.
5. The composition for forming an insulating material used in electronic devices according to 4, wherein in the formula (I) X is a methyl group, a trifluoromethyl group or ═O formed by combination of two Xs; and R¹ and R² are hydrogen atoms;

in the formula (II) wherein t is an integer of 6 to 14 and u is an integer of 0 to 9; and

in the formulas (II-1) and (II-2) wherein R³ and R⁴ are hydrogen atoms.

6. An insulating material used in electronic devices that is a polymer material obtained by curing the composition for forming an insulating material used in electronic devices according to any of 1 to 5.
7. An electronic device which uses the insulating material used in electronic devices according to 6 as a planarized film, a passivation film, an interlayer insulating film or a gate insulating film.
8. A thin film transistor comprising three terminals of a gate electrode, a source electrode and a drain electrode, an insulator layer and a semiconductor layer in which source-drain current is controlled by applying a voltage to the gate electrode, wherein the insulating material used in electronic devices according to claim 6 is used in the insulator layer.
9. The thin film transistor according to 8 wherein the semiconductor layer comprises an organic semiconductor.

When the composition of the invention is used for forming a gate insulator layer, the insulator layer can be formed by a solution method. An insulating material obtained by curing this can withstand the subsequent steps of a solution treatment due to the presence of a cross-linking structure. Further, due to a high heat resistance, it can withstand the process temperature applied in the subsequent processes. In addition, the insulating material has a small leakage current density. Therefore, by using this insulating material, a thin film transistor (TFT) having high field effect transistor (FET) properties can be realized.

According to the invention, in addition to a TFT, other electronic devices which are required to be formed into a film by a solution method, which has solvent resistance in the subsequent film formation in the subsequent solution method, heat resistance and a low leakage current density can be provided.

### BRIEF DESCRIPTION OF THE DRAWINGS

FIG. 1 is a view showing the device configuration of one embodiment of the thin film transistor of the invention;

FIG. 2 is a view showing the device configuration of another embodiment of the thin film transistor of the invention;

FIG. 3 is a view showing the device configuration of another embodiment of the thin film transistor of the invention;

FIG. 4 is a view showing the device configuration of another embodiment of the thin film transistor of the invention;

FIG. 5 is a view showing the device configuration of another embodiment of the thin film transistor of the invention; and

FIG. 6 is a view showing the device configuration of another embodiment of the thin film transistor of the invention.

### MODE FOR CARRYING OUT THE INVENTION

The composition for forming an insulating material used in electronic devices of the invention (hereinafter often referred to as the “composition of the invention”) is characterized in that it comprises, as a polymerizable component, a monomer comprising two or more (meth)acrylic moieties and a polycyclic alicyclic structure (hereinafter often referred to as the “polyfunctional polycyclic alicyclic monomer”).

It is required that the polyfunctional polycyclic alicyclic monomer used in the invention have two or more (meth)acrylic moieties. Due to the presence of two or more polymerizable functional groups, a cured film having higher solvent resistance and heat resistance by cross linking during polymerization or by cross linking after polymerization can be obtained. Although the number of (meth)acrylic moieties is not particularly limited as long as it is adjusted according to the reactivity or rigidity or the like of a monomer used, 2 to 4 moieties are preferable.

It is preferred that the composition of the invention comprise the polyfunctional polycyclic alicyclic monomer as a primary polymerizable component. The “primary” means that, of the polymerizable components contained in the composition, the amount of the polyfunctional polycyclic alicyclic monomer is 40 wt % or more, for example, and preferably 50 wt % or more. Therefore, within a range that does not impair attainment of the object of the invention, the composition of the invention may comprise a polymerizable component such as a monomer having one (meth)acrylic moiety and two or more (meth)acrylic moieties. All of the compositions of the invention may be polyfunctional polycyclic alicyclic monomers.

The polycyclic alicyclic structure constituting the polyfunctional polycyclic alicyclic monomer used in the invention is preferably a structure which may have a hetero atom and has 5 to 20 carbon atoms that form a ring (hereinafter referred to as the “ring carbon atoms”). For example, a hydrocarbon compound having a polycyclic structure such as a decalyl ring (perhydronaphthalene ring), a norbornyl ring, a bornyl ring, an isobornyl ring, an adamantyl ring, a tricyclo[5.2.1.0^{2,6}]decane ring and a tetracyclo[4.4.0.1^{2,5}.1^{7,10}]dodecane ring; a polycyclic lactone such as 4-oxa-tricyclo[4.2.1.0^{3,7}]nonane-5-on, 4,8-dioxa-tricyclo[4.2.1.0^{3,7}]nonane-5-on, 4-oxa-tricyclo[4.3.1.1^{3,8}]undecan-5-on, a polycyclic ether and a perfluoro substitute thereof can be given. In respect of resistance to solvents and leakage current density, an adamantyl ring and a tricyclo[5.2.1.0^{2,6}]decane ring are preferable.

These polycyclic alicyclic structures may have a substituent. As the substituent, a halogen atom such as a fluorine atom, an alkyl group having 1 to 20 carbon atoms and an alicyclic group having 3 to 20 ring carbon atoms can be given.

The alkyl group having 1 to 20 carbon atoms may be either straight chain or branched chain. For example, a methyl group, an ethyl group, various propyl groups, various butyl groups, various pentyl groups, various hexyl groups, various heptyl groups, various octyl groups, various nonyl groups, various decyl group, various dodecyl groups, various tetradodecyl groups, various hexadecyl groups, various octadecyl groups, and various icosyl groups or the like can be given.

As the alicyclic group having 3 to 20 ring carbon atoms, a cyclopentyl group, a cyclohexyl group, a cyclooctyl group, a cyclododecyl group, an adamantyl group and a group in which a lower alkyl group having about 1 to 5 carbon atoms is introduced on these rings can be given. As the lower alkyl group having about 1 to 5 carbon atoms, the groups mentioned above can be given.

As the polyfunctional polycyclic alicyclic monomer having two or more (meth)acrylic moieties and further having a polycyclic alicyclic structure, one having two (meth)acrylic moieties is preferable in respect of reducing the leakage current density. In this case, as compared with a structure in which the same alicyclic groups constituting the polycyclic alicyclic structure has two (meth)acrylic moieties, a structure in which different alicyclic groups respectively have one (meth)acrylic moiety is preferable in respect of leakage current density or durability. In the case of a structure in which three or more (meth)acrylic moieties are present, a structure in which different alicyclic groups constituting the polycyclic alicyclic structure has a (meth)acrylic moiety is preferable. As mentioned later, in the case of an adamantyl ring, a structure in which a group comprising a (meth)alkyl group is bonded to the 3^{rd} and 7^{th} positions of adamantane is preferable.

As compared with a structure in which a (meth)acryloyl group and a polycyclic alicyclic structure are directly bonded, a structure in which they are bonded through an alkylene group or an oxyalkylene group is preferable in respect of heat resistance.

As a monomer which has two or more (meth)acrylic moieties and further has a polycyclic alicyclic group and does not have an adamantyl ring, the following can be given, for example.

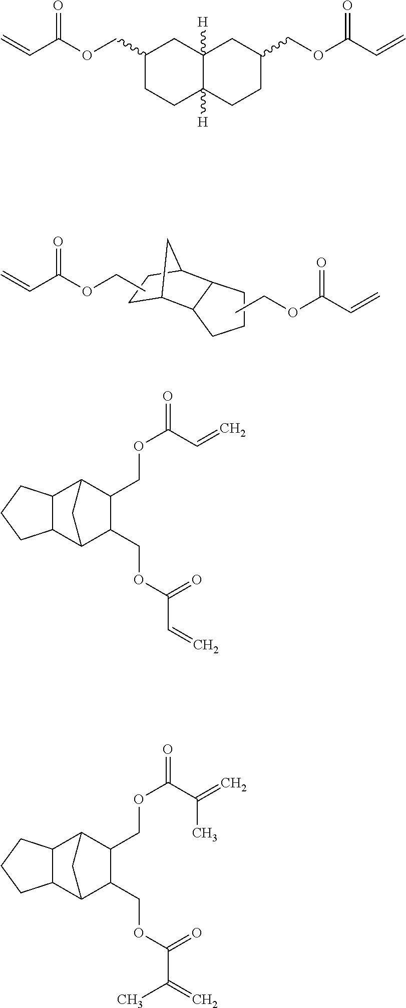

As the polyfunctional polycyclic alicyclic monomer having a structure containing adamantane as a polycyclic alicyclic structure, the following can be given, for example. However, an adamantane derivative represented by the formula (I) or (II) is preferable in respect of obtaining an electronic device having excellent performance.

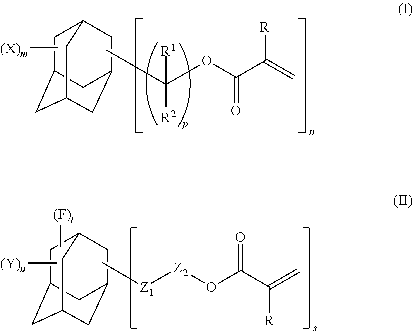

In the formula, R is a hydrogen atom, a fluorine atom, a methyl group or a trifluoromethyl group; X is a fluorine atom, a methyl group, a trifluoromethyl group or ═O formed by combination of two Xs; and Y is ═O formed by combination of two Ys.

R¹ and R² are independently a hydrogen atom, a halogen atom or an alkyl group having 1 to 5 carbon atoms. As the alkyl group having 1 to 5 carbon atoms, the groups mentioned above can be given.

p is an integer of 0 to 6; m is an integer of 0 to 14, n is an integer of 2 or more, t is an integer of 0 to 14, u is an integer of 0 to 14, and s is an integer of 2 or more, and plural Xs and plural Ys may be the same or different.

Z₁ is a group represented by —C_{(q+r)}F_{2q}H₂ᵣ— (q is an integer of 0 to 4 and r is an integer of 0 to 4); and Z₂ is a single bond or a group represented by the following formula (II-1) or (II-2):

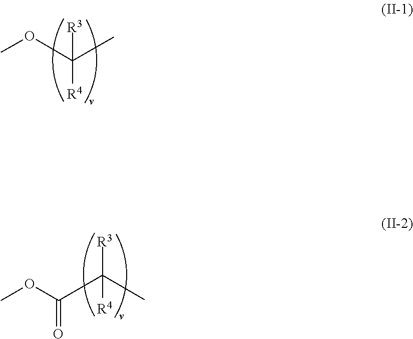

In the formulas (II-1) and (II-2), v is an integer of 1 to 4 and R³ and R⁴ are independently a hydrogen atom, a halogen atom or an alkyl group having 1 to 5 carbon atoms. As the alkyl group having 1 to 5 carbon atoms, the groups mentioned above can be given.

In the formula (I), it is preferred that R be a hydrogen atom or a methyl group in respect of easiness in availability. Further, a structure in which a group containing a (meth)alkyl group is bonded to the 3^{rd} and 7^{th} positions of adamantane is preferable in view of leakage current density. It is preferred that R¹ and R² be a hydrogen atom. m is preferably 0 in respect of availability. n is preferably 2 in respect of leakage current density. p is preferably an integer of 1 to 6 in respect of heat resistance.

In the formula (II), it is preferred that R be a hydrogen atom or a methyl group in respect of easiness in availability. Further, a structure in which a group containing a (meth)alkyl group is bonded to the 3^{rd} and 7^{th} positions of adamantane is preferable in view of leakage current density. s is preferably 2 in respect of leakage current density. It is preferred that t be 14 and u be 0 in respect of easiness in availability and surface energy. —C_{(q+r)}F_{2q}H₂ᵣ— in Z₁ may be —C_{q}F_{2q}CᵣH₂ᵣ—. q is preferably an integer of 0 or 1. r is preferably an integer of 0 or 1. Z₂ is preferably represented by the formula (II-1). It is preferred that R³ and R⁴ be a hydrogen atom.

As other adamantane derivatives, those represented by the formulas (III) to (XI-9) can be given.

An adamantane derivative represented by the following formula (III):

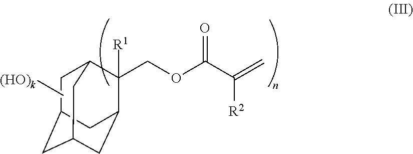

wherein R¹ is a group selected from an acrylate group, a methacrylate group and a trifluoromethacrylate group; R² is a group selected from a hydrogen atom, a methyl group and a trifluoromethyl group; k is an integer of 0 to 4; and n is an integer of 1 to 6.

The group in the parenthesis can be bonded to 6 methylene parts in the adamantane skeleton.

k may be 1 or more. However, when used as a composition for forming an insulating material used in electronic devices, a hydroxyl group is required to be sealed by using a silane compound or the like.

Specific examples of the compound represented by the above formula (III), the following compounds can be given, for example.

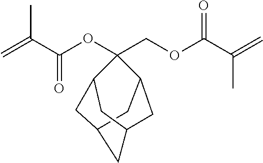 [SMILES: C=C(C)C(=O)OCC1(OC(=O)C(=C)C)C2CC3CC(C2)CC1C3]

An adamantane derivative represented by the following formula (IV):

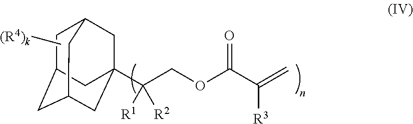

wherein R¹ is a hydrocarbon group represented by CₚH₂ₚ₊₁ (p is an integer of 1 to 7); R² is a (meth)acryloyloxy group or a trifluoromethacryloyloxy group; R³ is a hydrogen atom, a methyl group or a trifluoromethyl group; and R⁴ is a methyl group, a hydroxyl group, a carboxyl group or ═O formed by combination of two R⁴s. n is an integer of 1 to 4, k is an integer of 0 to 4 and a plurality of R¹ and R⁴ may be the same or different.

The groups in the parenthesis can be bonded to 4 methine parts in the adamantane skeleton.

R¹ is preferably an alkyl group having 1 to 10 carbon atoms. Specific examples thereof include the above-mentioned groups. When R⁴ is a hydroxyl group and this derivative is used as a composition for forming an insulating material used in electronic devices, it is required to seal the hydroxyl group by using a silane compound or the like. Further, in the case of a carboxyl group, it is required to seal a terminal hydroxyl group by esterification or the like.

As specific examples of the compound represented by the above formula (IV), the following compound can be given, for example.

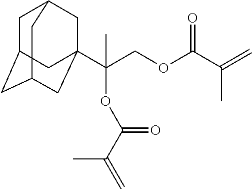 [SMILES: C=C(C)C(=O)OCC(C)(OC(=O)C(=C)C)C12CC3CC(CC(C3)C1)C2]

An adamantane derivative represented by the following formula (V):

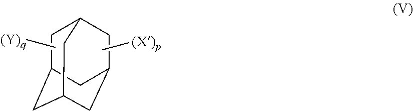

wherein Y is a group selected from a fluorine atom, a hydrocarbon group having 1 to 10 carbon atoms, a hydroxyl group and a carboxyl group; q is an integer of 0 to 15; when q is 2 or more, it may be ═O formed by combination of two Ys; and a plurality of Ys may be the same or different; X is a monovalent group represented by the following formula (VI):

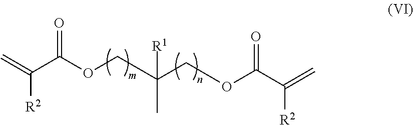

wherein R¹ is a group selected from a hydrogen atom, a fluorine atom, a hydrocarbon group having 1 to 10 carbon atoms, a hydroxyl group and a carboxyl group or a trifluoromethyl group; R² is a hydrogen atom, a methyl group or a trifluoromethyl group; n and m are independently an integer of 0 to 4, provided that there is no case that n and m are both 0; p is an integer of 1 to 4, and when p is 2 or more, plural X's may be the same or different; and p+q is an integer of 1 to 16.

When Y or R¹ is a hydroxyl group or a carboxyl group and this derivative is used as a composition for forming an insulating material used in electronic devices, it is required to seal the terminal hydroxyl group by using a silane compound or by esterification or the like. When Y or R¹ is a hydrocarbon group having 1 to 10 carbon atoms, it is preferably an alkyl group having 1 to 10 carbon atoms. Specific examples thereof include those mentioned above.

An adamantyl di(meth)acrylate mixture of a di(meth)acrylate product represented by the following formula (VII-i) and a Michael adduct represented by the following formula (VII-ii), the mixture having a content of a Michael adduct of 5 to 40 wt %.

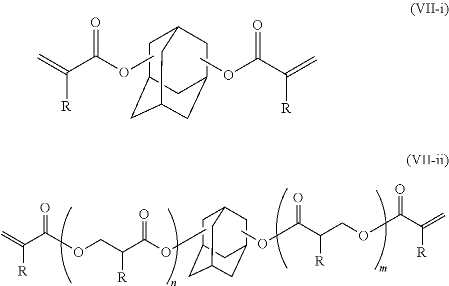

wherein R is independently a hydrogen atom, a methyl group, a fluorine atom or a trifluoromethyl group, and n and m are integers of 1 to 20.

Fluorine-containing adamantane derivative represented by the formula (VIII):

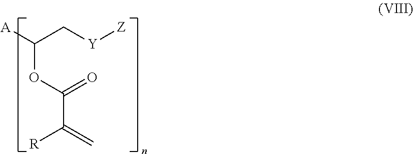

wherein A is a single bond or a n-valent hydrocarbon group having 1 to 10 carbon atoms that may have a substituent. Y is an oxygen atom or a divalent hydrocarbon group which may comprise an oxygen atom. As the divalent hydrocarbon group, an alkylene group having 1 to 10 carbon atoms such as a methylene group or a difluoromethylene group or a fluoroalkylene group can be given. Z is an adamantyl group of which one or more hydrogen atoms is replaced by a fluorine atom. R is a hydrogen atom, a fluorine atom, a methyl group or a trifluoromethyl group. n is an integer of 2 to 4.

Adamantane derivative represented by the following formula (IX):

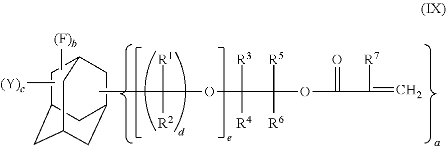

wherein Y is one selected from a hydrogen atom, an organic group, a hydroxyl group and a ═O group formed by combination of two Ys; R¹ to R⁶ are independently one selected from a hydrogen atom, a halogen atom, a hydroxyl group, an aliphatic hydrocarbon group which may contain a hetero atom and a perfluoroalkyl group or a ═O group formed by combination of R¹ and R². However, at least one of R³ to R⁶ is a substituent represented by (M):-A-B (wherein in the formula (M), A is a straight-chain, branched or cyclic aliphatic hydrocarbon group having 1 to 10 carbon atoms that may contain an ether bond (—O—) or an ester bond (—COO—). B is an organic group containing a straight-chain, branched or cyclic fluoroalkyl group having 1 to 20 carbon atoms which may contain an ether bond or an ester bond.

R⁷ is one selected from a hydrogen atom, a fluorine atom, a methyl group and a trifluoromethyl group.

a is an integer of 2 to 4, b is an integer of 1 to 14, c is 0 or an integer of 1 to 13, and a+b+c=16. d is 0 or an integer of 1 to 5, and e is an integer of 1 to 5. Plural Ys and R¹ to R⁶ may be the same or different. Plural

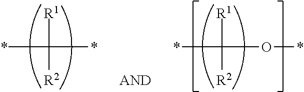

may be the same or different.

When Y and R¹ to R⁶ are hydroxyl groups and this derivative is used as a composition for forming an insulating material used in electronic devices, it is required to seal a hydroxyl group by using a silane compound or the like. When Y or R¹ to R⁶ are an organic group or an aliphatic hydrocarbon group which may contain a hetero atom, as the organic group or the aliphatic hydrocarbon, an alkyl group having 1 to 10 carbon atoms is preferable. As specific examples thereof, the groups as mentioned above can be given. Further, it is preferred that A be a straight-chain hydrocarbon group having 1 to 3 carbon atoms. A methylene group, an ethylene group and a 1,3-propylene group are further preferable. It is preferred that B be a perfluoroalkyl group having 1 to 5 carbon atoms.

Adamantane derivative represented by the following formula (X):

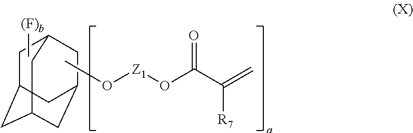

wherein Z₁ is a group represented by

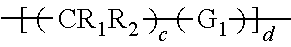

wherein R₁ and R₂ are independently hydrogen, halogen, a hydroxyl group, an aliphatic hydrocarbon group which may contain an oxygen atom, or an organic group represented by the formula (A):

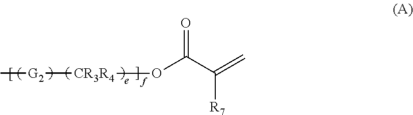

wherein R₃ and R₄ are independently hydrogen, halogen, a hydroxyl group or an aliphatic hydrocarbon group which may contain an oxygen atom.

G₁ and G₂ are independently a single bond or an oxygen atom. c to f are independently an integer of 1≦c≦10, 1≦d≦10, 0≦e≦10 and 0≦f≦10.

a and b are independently 2≦a≦4 and 10≦b≦14 and a+b=16.

R₇ is hydrogen, a methyl group or a trifluoromethyl group. However, when a is 2, at least one of R₁ and R₂ is an organic group represented by the formula (A).

When R₁ to R₄ are a hydroxyl group and this derivative is used as a composition for forming an insulating material used in electronic devices, it is required to seal the hydroxyl group by using a silane compound or the like. As the aliphatic hydrocarbon group in R₁ to R₄, an alkyl group having 1 to 10 carbon atoms can be given.

Adamantane derivative represented by the following formulas (XI-1) to (XI-4):

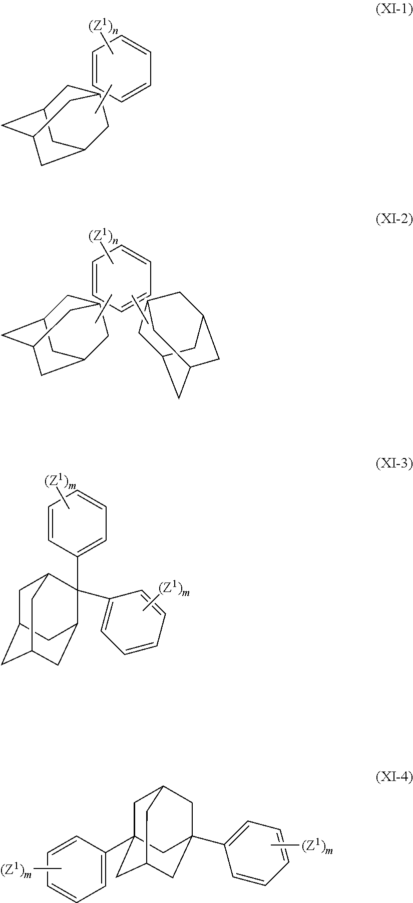

wherein Z¹ is represented by the following formula (XI-5):

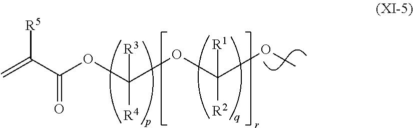

wherein R¹ to R⁴ are independently a hydrogen atom, a fluorine atom, a hydrocarbon group having 1 to 10 carbon atoms, a hydroxyl group, a carboxyl group or a trifluoromethyl group; R⁵ is a hydrogen atom, a fluorine atom, a methyl group or a trifluoromethyl group; p is an integer of 2 to 10; q is an integer of 0 to 10; r is an integer of 0 to 5, and when p, q and r are independently an integer of 2 or more, R¹ to R⁴ may be the same or different.

n is an integer of 2 to 4; plural Z¹s may be the same or different; m is an integer of 1 to 4, and when m is 2 or more, plural Z¹s may be the same or different.

When R¹ to R⁴ are a hydroxyl group and this derivative is used as a composition for forming an insulating material used in electronic devices, it is required to seal the hydroxyl group by using a silane compound or the like. In the case of a carboxyl group, it is required to seal a terminal hydroxyl group by esterification or the like. Further, as the hydrocarbon group having 1 to 10 carbon atoms in R¹ to R⁴, an alkyl group having 1 to 10 carbon atoms is preferable.

Adamantane derivative represented by the following formulas (XI-6) to (XI-9):

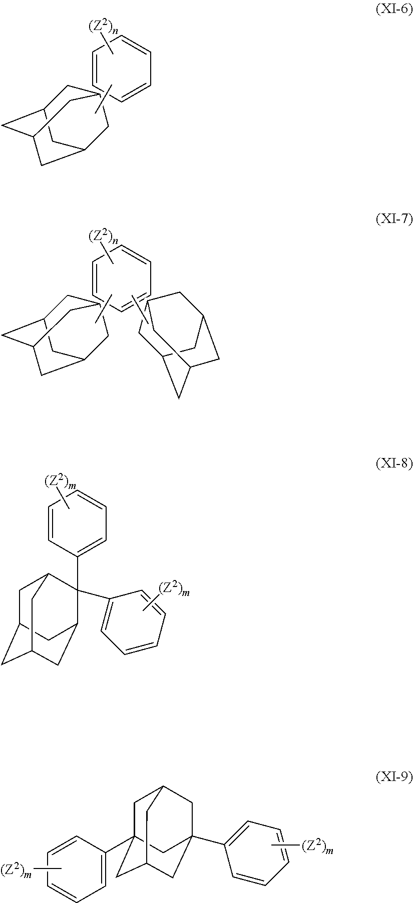

wherein Z² is represented by the following formula (XI-10):

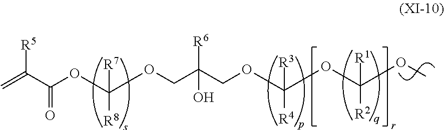

wherein R¹ to R⁴ and R⁶ to R⁸ are independently a hydrogen atom, a fluorine atom, a hydrocarbon group having 1 to 10 carbon atoms, a hydroxyl group, a carboxyl group or a trifluoromethyl group; R⁵ is a hydrogen atom, a fluorine atom, a methyl group or a trifluoromethyl group; p is an integer of 2 to 10; q is an integer of 0 to 10; r is an integer of 0 to 5; s is an integer of 0 to 6, and when p, q, r and s are independently 2 or more, R¹ to R⁴, R⁷ and R⁸ may be the same or different;

n is an integer of 2 to 4, and plural Z²s may be the same or different; m is an integer of 1 to 4 and when m is 2 or more, plural Z²s may be the same or different.

When R¹ to R⁴ and R⁶ to R⁸ are a hydroxyl group and this derivative is used as a composition for forming an insulating material used in electronic devices, it is required to seal the hydroxyl group by using a silane compound or the like. A hydroxyl group in the formula (XI-10) is required to be sealed. In the case of a carboxyl group, a terminal hydroxyl group is required to be seal by esterification or the like. Further, as the hydrocarbon group having 1 to 10 carbon atoms in R¹ to R⁴ and R⁶ to R⁸, an alkyl group having 1 to 10 carbon atoms is preferable.

In addition to those mentioned above, the following adamantane derivatives can be exemplified.

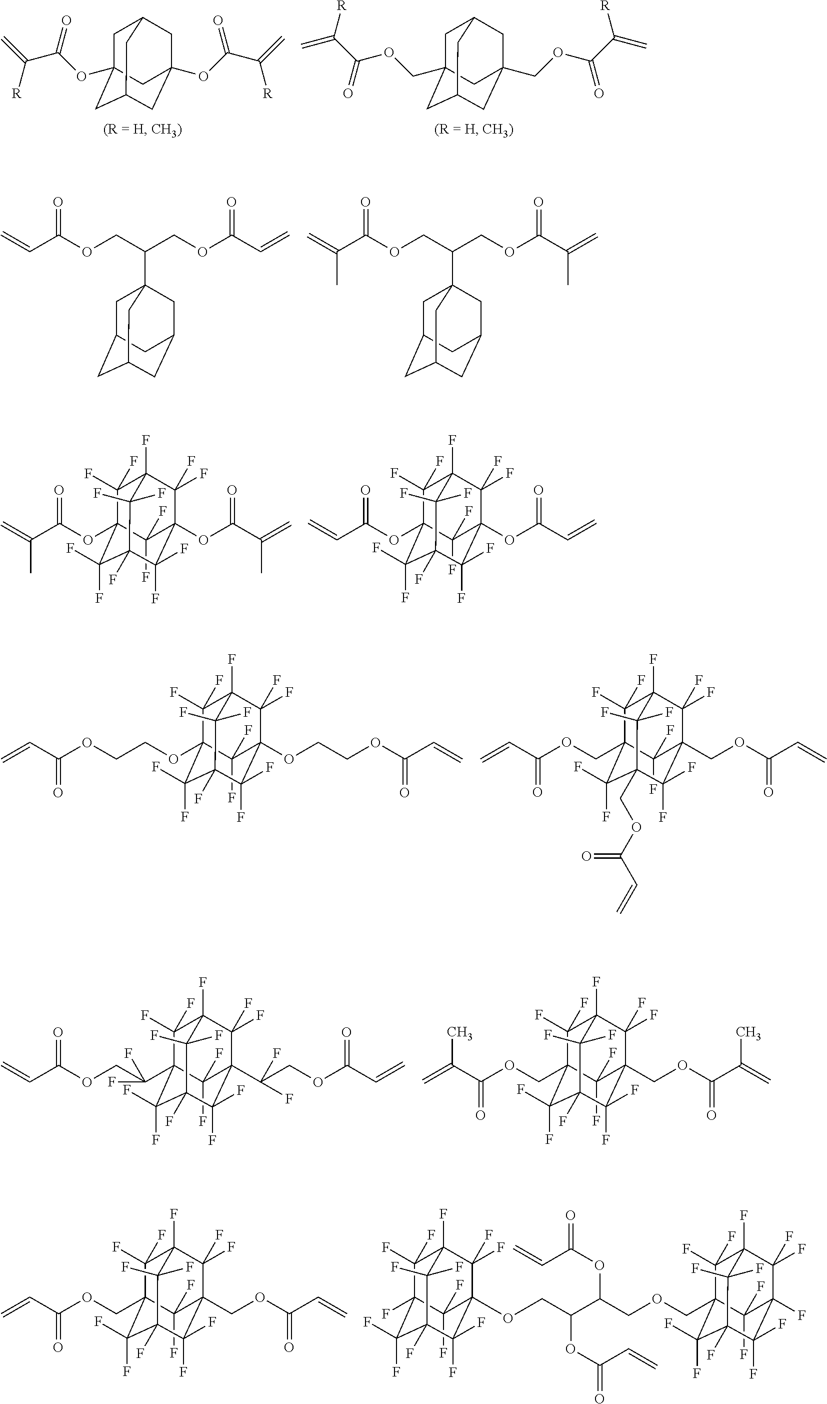

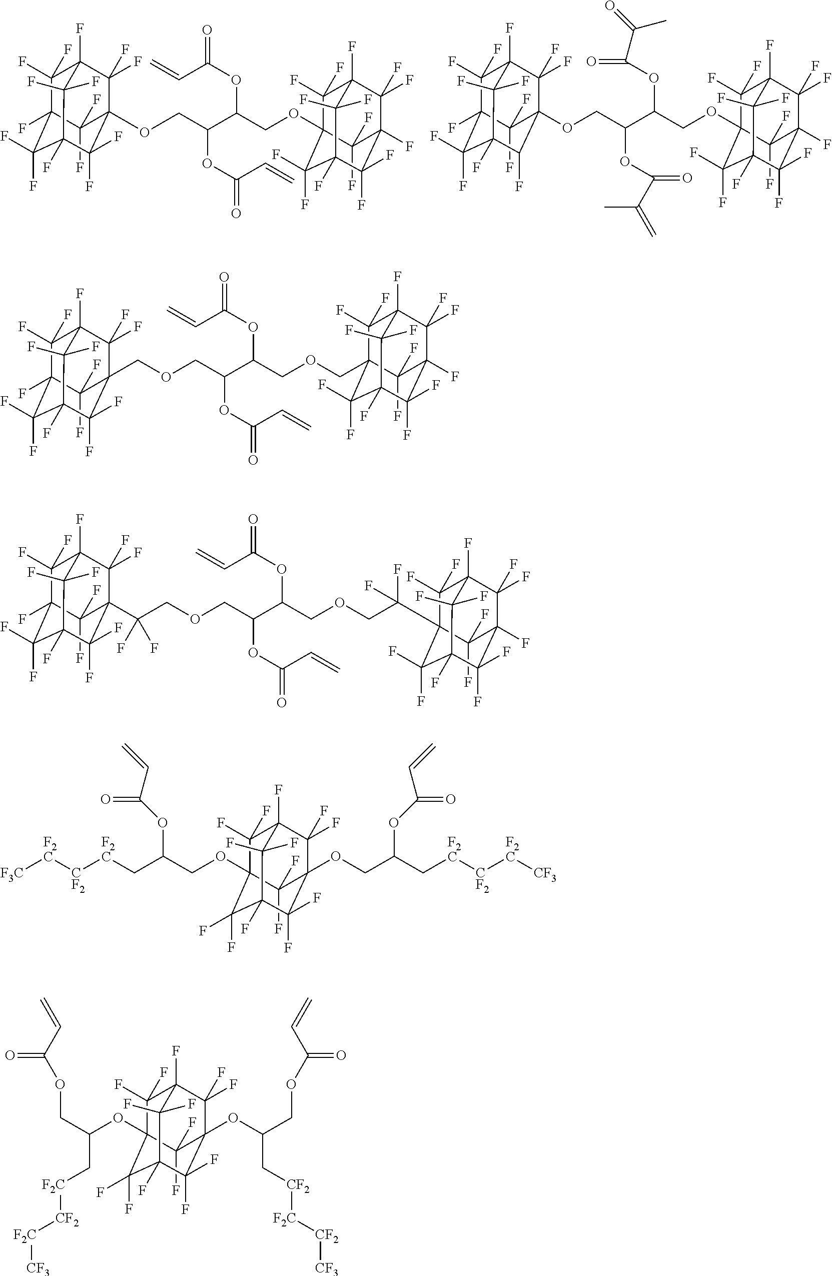

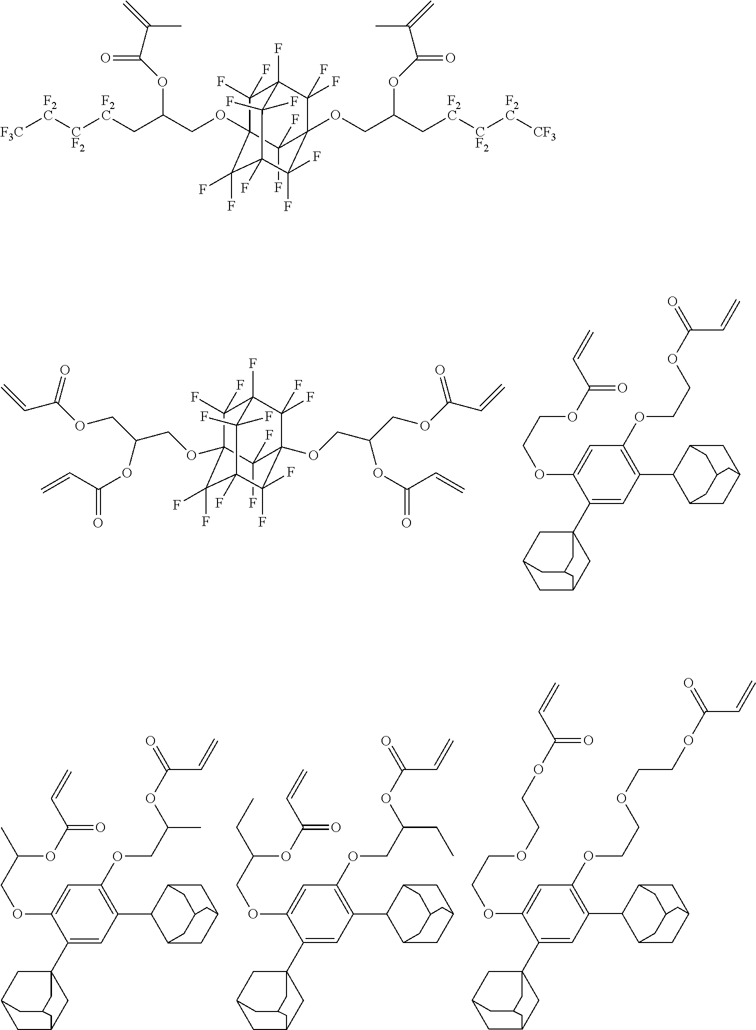

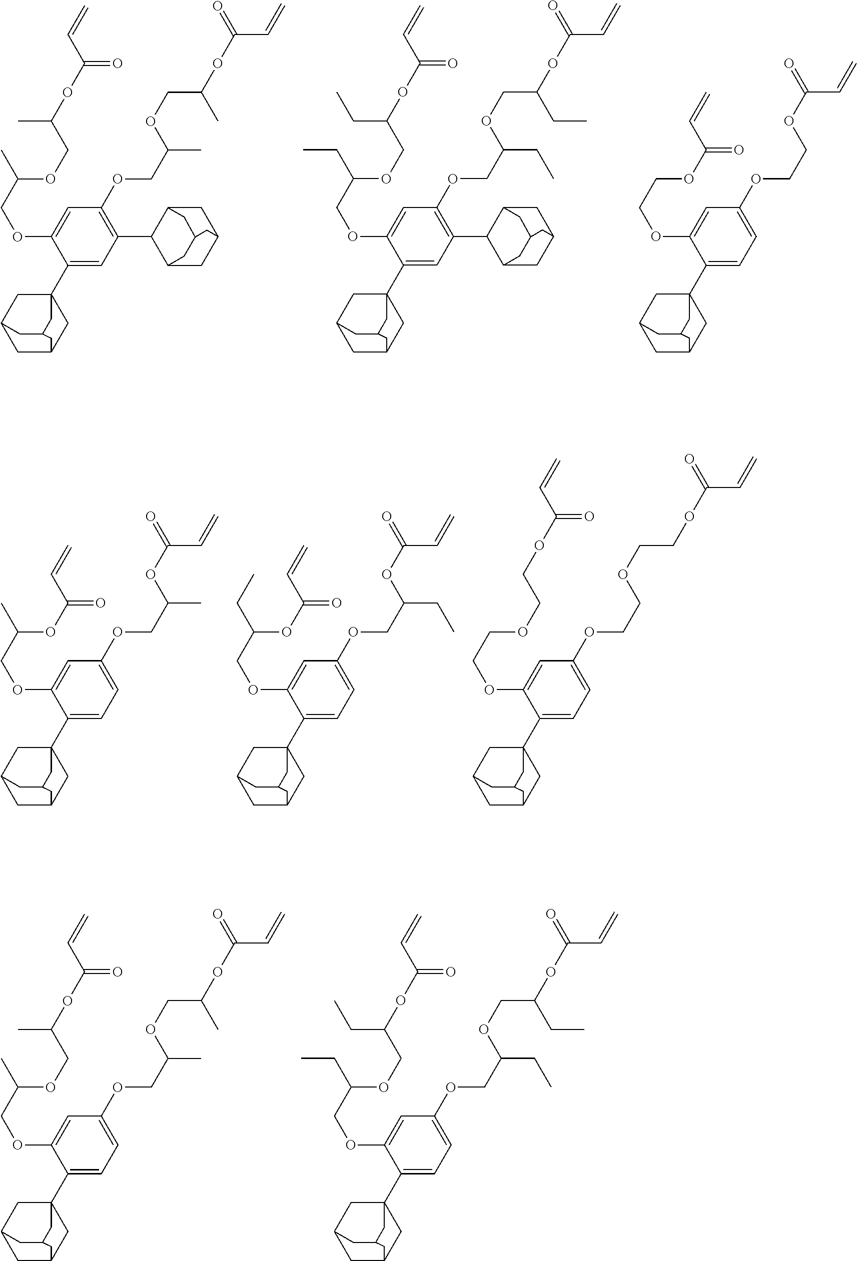

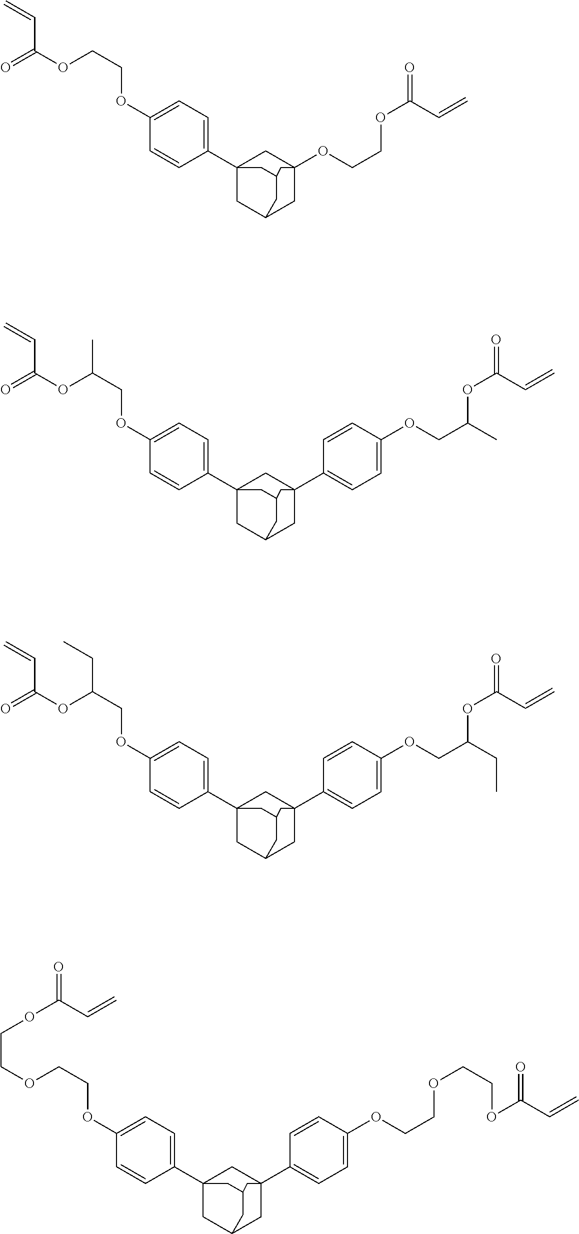 [SMILES: C=CC(=O)OCCOc1ccc(C23CC4CC(CC(OCCOC(=O)C=C)(C4)C2)C3)cc1 ; C=CC(=O)OC(C)COc1ccc(C23CC4CC(C2)CC(c2ccc(OCC(C)OC(=O)C=C)cc2)(C4)C3)cc1 ; C=CC(=O)OC(CC)COc1ccc(C23CC4CC(C2)CC(c2ccc(OCC(CC)OC(=O)C=C)cc2)(C4)C3)cc1 ; C=CC(=O)OCCOCCOc1ccc(C23CC4CC(C2)CC(c2ccc(OCCOCCOC(=O)C=C)cc2)(C4)C3)cc1]

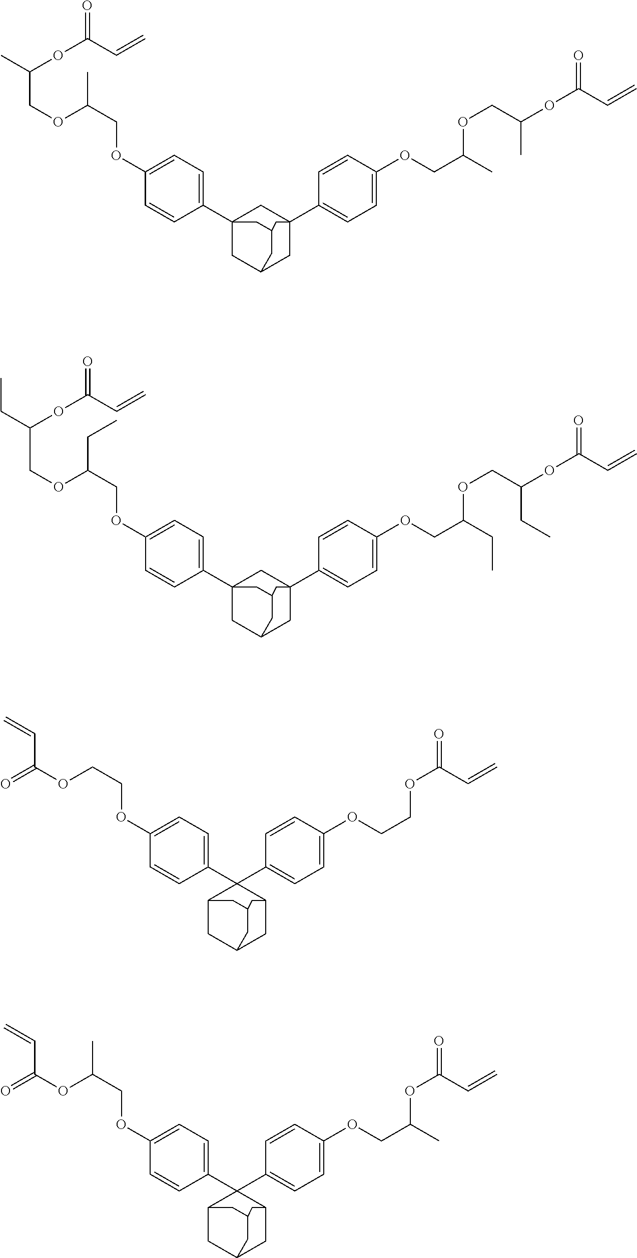

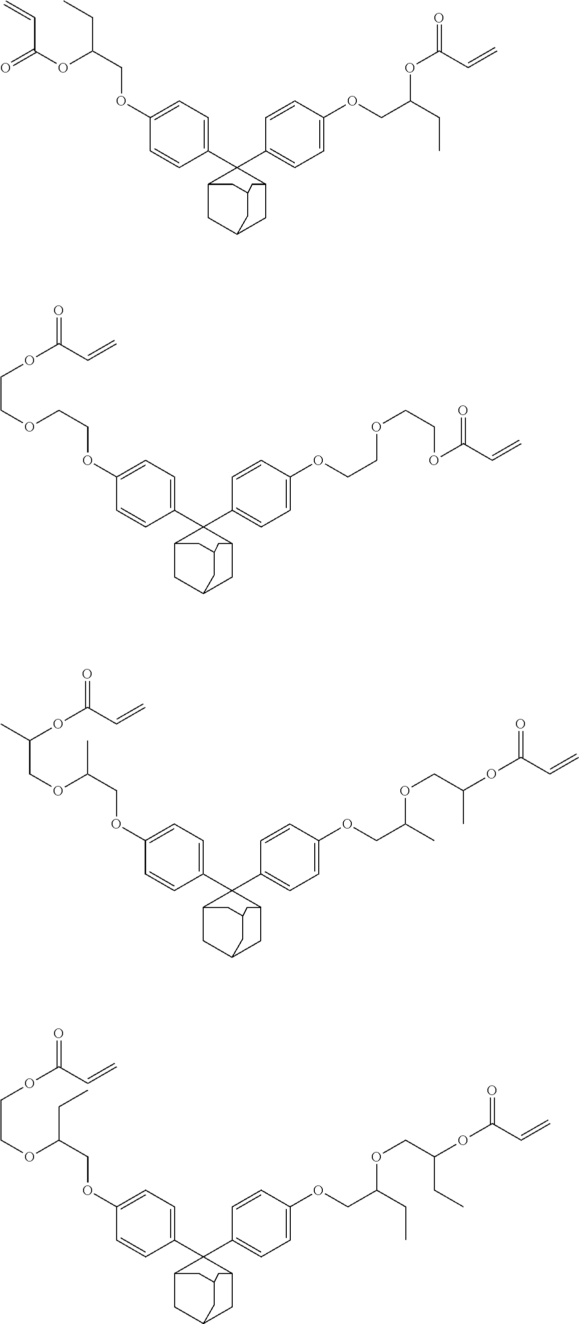

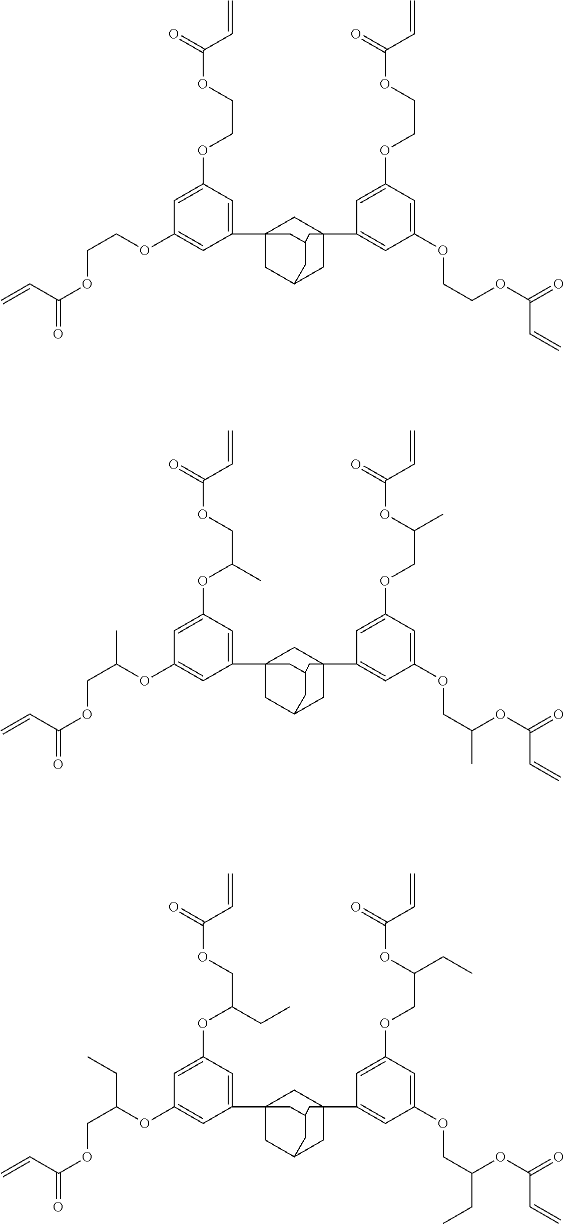

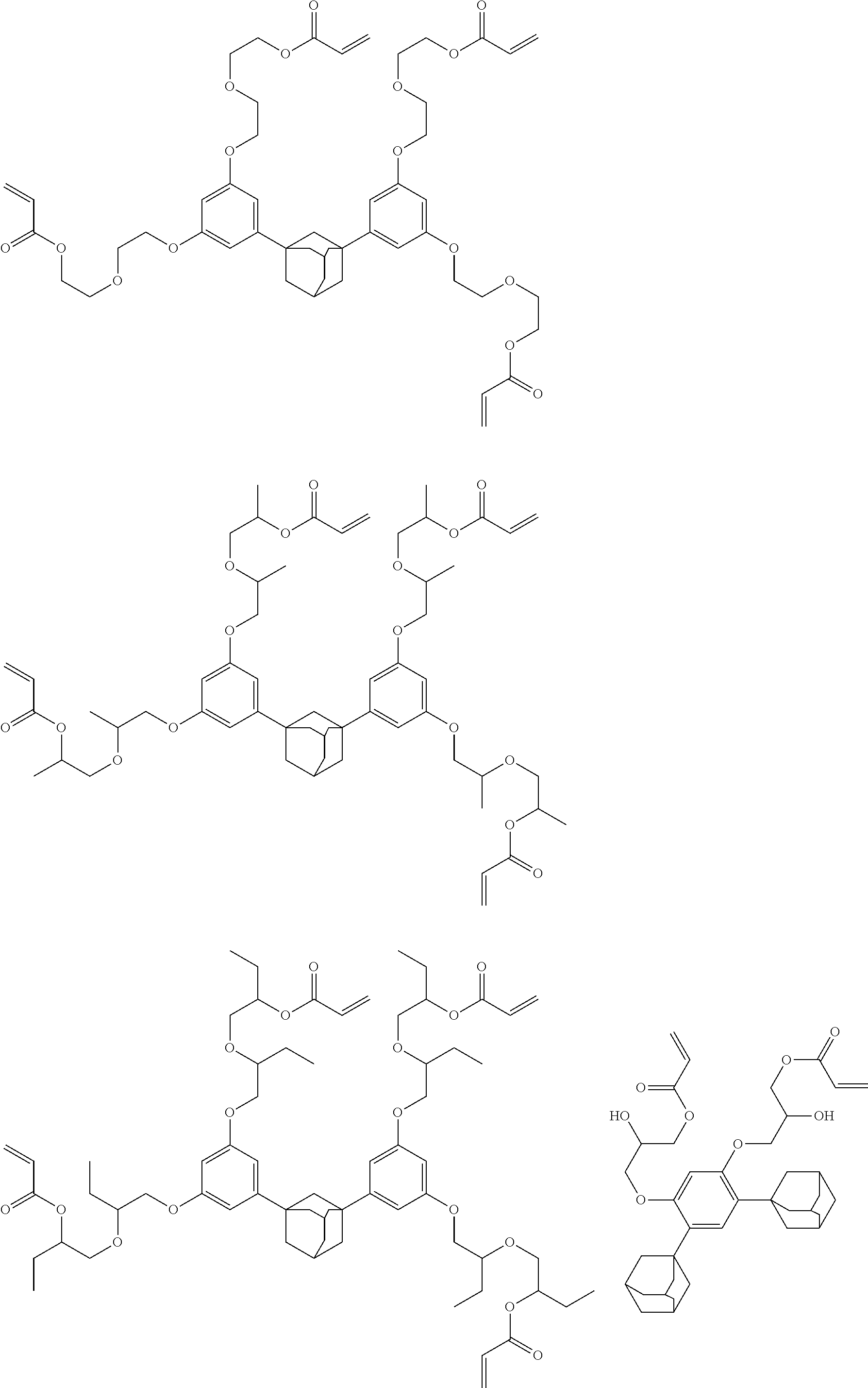

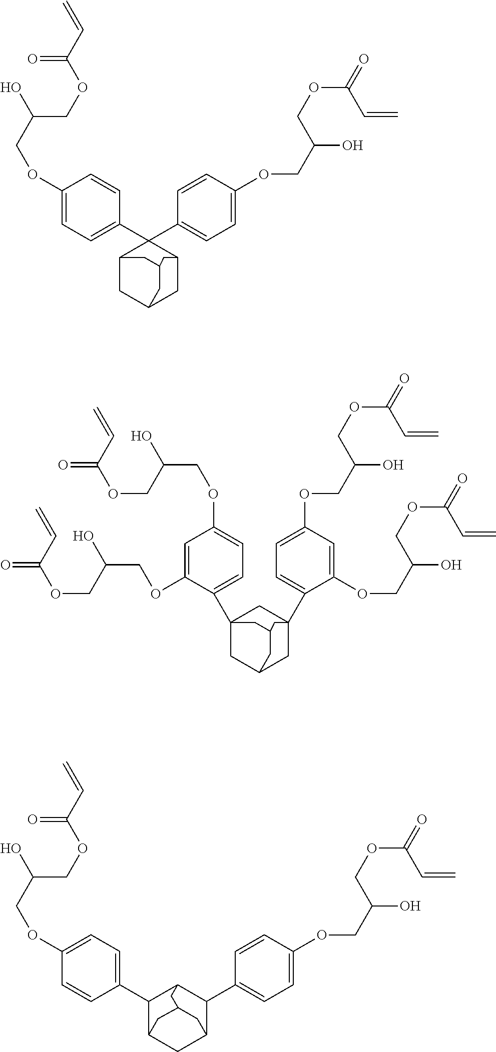 [SMILES: C=CC(=O)OCC(O)COc1ccc(C2(c3ccc(OCC(O)COC(=O)C=C)cc3)C3CC4CC(C3)CC2C4)cc1 ; C=CC(=O)OCC(O)COc1ccc(C23CC4CC(C2)CC(c2ccc(OCC(O)COC(=O)C=C)cc2OCC(O)COC(=O)C=C)(C4)C3)c(OCC(O)COC(=O)C=C)c1 ; C=CC(=O)OCC(O)COc1ccc(C2C3CC4CC(C3)C(c3ccc(OCC(O)COC(=O)C=C)cc3)C2C4)cc1]

The polyfunctional polycyclic alicyclic monomer used in the invention can be produced by reacting a known polycyclic alicyclic diol or the like with a (meth)acrylic acid or its reactive derivative, for example. Specifically, it can be synthesized by using an azeotropic dehydration method, an acid halide method or an ester exchange method, which is generally known, a polycyclic alicyclic diol or the like is reacted with a (meth)acrylic acid or its reactive derivative to conduct esterification.

Examples of an adamantyl group-containing diol include 1,3-adamantane diol, adamantane-1,3-dimethanol, adamantane-1,3-diethanol, adamantane-1,3-dipropanol, adamantane-1,3,5-trimethanol, adamantane-1,3,5-triethanol, adamantane-1,3,5-tripropanol, adamantane-1,3,5,7-tetramethanol, adamantane-1,3,5,7-tetraethanol, adamantane-1,3,5,7-tetrapropanol or the like.

Other adamantyl group-containing diols include perfluoro-1,3-adamantane diol, perfluoro-1,3-bis(2-hydroxyethoxy)adamantane, perfluoro-1,3,5-tris(2-hydroxyethoxy)adamantane, perfluoro-1,3,5,7-tetrakis(2-hydroxyethoxy)adamantane, perfluoro-1,3-bis(2-hydroxypropoxy)adamantane, perfluoro-1,3,5-tris(2-hydroxypropoxy)adamantane, perfluoro-1,3,5,7-tetrakis(2-hydroxypropoxy)adamantane, perfluoro-1,3-bis(2-hydroxybutoxy)adamantane, perfluoro-1,3,5-tris(2-hydroxybutoxy)adamantane, perfluoro-1,3,5,7-tetrakis(2-hydroxybutoxy)adamantane, perfluoro-1,3-bis(2-hydroxypentyloxy)adamantane, perfluoro-1,3,5-tris(2-hydroxypentyloxy)adamantane, perfluoro-1,3,5,7-tetrakis(2-hydroxypentyloxy)adamantane or the like.

As the (meth)acrylic acid or its reactive derivative, in the case of the above-mentioned azeotropic dehydration method, acrylic acid, methacrylic acid, α-trifluoromethyl acrylic acid, α-fluoroacrylic acid and acid anhydrides such as acrylic acid anhydride, methacrylic acid anhydride, α-trifluoromethylacrylic anhydride and α-fluoroacrylic acid anhydride can be given.

In the case of the above-mentioned acid halide method, acid halides such as acrylic acid chloride, methacrylic acid chloride, α-trifluoromethyl acrylic acid chloride and α-fluoroacrylic acid chloride can be given.

In the case of the above-mentioned ester exchange method, methyl acrylate, ethyl acrylate, propyl acrylate and a lower alkyl ester obtained by substituting the acrylic acid part of these compounds with methacrylic acid, α-trifluoromethylacrylic acid and α-fluoroacrylic acid can be given.

The amount of the (meth)acrylic acid or its reactive derivative is preferably about 1 to 3 times larger than the chemical equivalent amount of the polycyclic alicyclic group-containing alcohol.

As the method for producing a monomer having two or more (meth)acrylic moieties and in which the polycyclic alicyclic structure is adamantane, a method stated in JP-A-2008-105999 can be used, for example.

By mixing these polyfunctional polycyclic alicyclic monomers and, optionally, a heat polymerization initiator or a photo polymerization initiator, and if necessary, an organic solvent, a composition for forming an insulating material used in electronic devices (the composition of the invention) can be produced.

The amount of the polyfunctional polycyclic alicyclic monomer is normally 50 to 100 wt % relative to 100 wt % of the polymerizable components contained in the composition. The polyfunctional polycyclic alicyclic monomer may be used singly or in combination of two or more.

Within a range which does not deviate from attaining the object of the invention, other polymerizable monomers can be polymerized by using a polymerization initiator which is common to that for the polyfunctional polycyclic alicyclic monomer used in the invention. In respect of possibility of polymerization by using the common polymerization initiator, a monomer having (meth)acrylic moieties is preferable. In respect of resistance to a solvent, a monomer having two or more (meth)acrylic moieties is further preferable. As such a monomer, a monomer used in Example 5 or 6 mentioned later can be given. A monomer which has (meth)acrylic moieties and does not have a polycyclic alicyclic group is inferior in heat resistance, and however, it can advantageously used in order to improve solvent resistance. One having three or more (meth)acrylic moieties exerts only small effect on the leakage current density.

The composition of the invention may contain a heat polymerization initiator when cured by heating and may contain a photopolymerization initiator when cured by light irradiation.

As the heat polymerization initiator, an organic peroxide such as benzoyl peroxide, methyl ethyl ketone peroxide, methyl isobutyl peroxide, cumene hydroperoxide, t-butyl hydroperoxide or an azo-based initiator such as azobisisobutyronitrile can be given.

As the photopolymerization initiator, acetophenone, benzophenone, benzil, benzoin ether, benzyl diketal, thioxanthone, acylphosphine oxide, an acylphosphine ester, an aromatic diazonium salt, an aromatic sulfonium salt, an aromatic iodonium salt, an aromatic iodosyl salt, an aromatic sulfoxonium salt, a metallocene compound or the like can be given.

The amount of these polymerization initiators is normally 0.01 to 10 wt % relative to 100 wt % of the entire amount of the composition excluding the organic solvent, and these initiators may be used singly or in combination of two or more.

Similarly, the composition of the invention may contain an organic solvent, if necessary. No specific restrictions are imposed on the organic solvent used, and specific examples thereof include a hydrocarbon-based solvent such as benzene, toluene, hexane and heptane; an ether-based solvent such as tetrahydrofuran, 1,4-dioxane, 1,3-dioxolane, anisole and diethylether; a ketone-based solvent such as acetone, methyl ethyl ketone (MEK), methyl isobutyl ketone and cyclohexanone; a glycol-based solvent such as propylene glycol-1-monomethyl ether-2-acetate (PGMEA) and ethylene glycol diethylether; and halogen-based solvent such as chloroform, methylene chloride and 1,2-dichloroethane can be given. An organic solvent may be used singly or in combination of two or more.

Although the amount of a solvent to be used can be suitably determined, the lower limit of the preferable amount used relative to 1 g of the entire amount of components other than the organic solvent contained in the curable composition is 0.1 mL and the upper limit of the preferable amount is 100 mL. If the amount is too small, advantageous effects brought about by using a solvent, for example, a decrease in viscosity, cannot be obtained. If the amount is too large, a solvent tends to remain in a material to cause problems such as occurrence of thermal cracks. In addition, a too large amount of the solvent is disadvantageous in respect of production cost. As a result, industrial value of using a solvent will be deteriorated.

In addition to the above-mentioned components, the composition of the invention may contain an additive such as a cross-linking agent, a surfactant, a coupling agent or the like as long as the effects of the invention are not impaired.

The insulating material for electronic devices of the invention (hereinafter often referred to as the “insulating material of the invention”) is characterized in that it comprises a polymer material obtained by curing the composition for forming an insulating material used in electronic devices of the invention.

By applying the composition to a location at which an insulating film is formed, followed by curing by heating or irradiation of light such as ultraviolet (UV) rays or the like, a cured product, i.e. a cross-linked polymer insulating material (the insulating material of the invention), can be produced.

The heat curing temperature when the composition of the invention is subjected to heat curing to obtain an insulating material is normally 30 to 200° C., preferably 50 to 150° C. When light curing is conducted, an active ray such as UV rays is irradiated, for example. Although the irradiation intensity is arbitrarily selected by the type of a polyfunctional polycyclic alicyclic monomer or a polymerization initiator, a film thickness of an insulating material or the like, it is normally 100 to 5000 mJ/cm², more preferably, 500 to 4000 mJ/cm².

A cured product of the composition for forming an insulating material used in electronic devices obtained in the invention is suitable for use as the insulating material used in electronic devices since it has excellent heat resistance and a low leakage current density.

As specific applications, elements for electronic devices which require a low leakage current density may be mentioned. For example, an element for an electronic device or an element of an electronic apparatus provided with an electronic device as the element thereof, which is in contact with an electrode or a semiconductor material, can be given.

As preferable applications, an application where reduction in film thickness and resistance to solvents are required can be given. For example, an insulating film for electronic devices such as a planarized film, a passivation film, an interlayer insulating film and a gate insulating film for a TFT can be given. Among them, a gate insulating film for a TFT in which a low leakage current density directly contributes to its performance can be given as a particularly preferable application.

Next, an explanation is given on a thin film transistor in which the insulating material for electronic devices of the invention is used in a gate insulator layer.

The thin film transistor of the invention comprises three terminals of a gate electrode, a source electrode and a drain electrode, an insulator layer and a semiconductor layer, and in which a source-drain current is controlled by applying a voltage to the gate electrode, wherein the insulating material for electronic devices of the invention is used in the insulator layer.

The thin film transistor of the invention can have several configurations depending on the position of electrodes, the stacking order of layers or the like, and has a structure of a field effect transistor (FET: Field Effect Transistor).

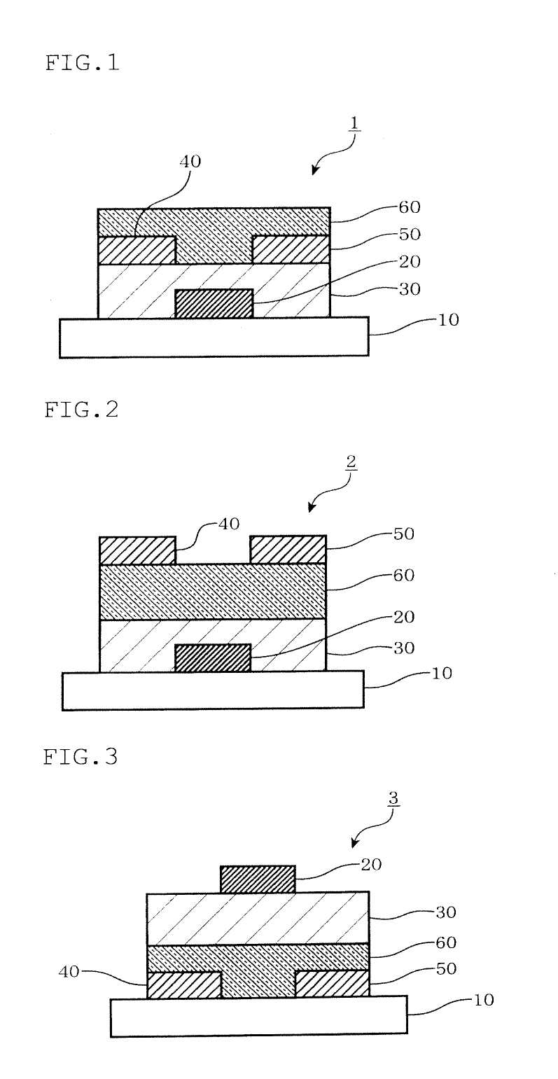

FIG. 1 is a view showing one embodiment of the thin film transistor of the invention.

In a thin film transistor 1, a gate electrode 20 is stacked on a substrate 10, and an insulator layer 30 is stacked on the substrate 10 such that it covers the gate electrode 20. On the insulator layer 30, a source electrode 40 and a drain electrode 50 are stacked in parallel with a predetermined interval being provided therebetween. A semiconductor layer 60 fills the gap between the source electrode 40 and the drain electrode 50, and is stacked on the insulator layer 30, the source electrode 40 and the drain electrode 50.

The semiconductor layer 60 forms a channel region, and conducts an on-off operation by control of current flowing between the source electrode 40 and the drain electrode 50 by a voltage applied to the gate electrode 20.

FIG. 2 is a view showing another embodiment of the thin film transistor of the invention.

In a thin film transistor 2, the semiconductor layer 60 is stacked on the insulator layer 30. It has a configuration similar to that of the thin film transistor 1, except that the source electrode 40 and the drain electrode 50 are stacked on the semiconductor layer 60 in parallel with a predetermined interval being formed therebetween.

FIG. 3 is a view showing another configuration of the thin film transistor of the invention.

In a thin film transistor 3, the source electrode 40 and the drain electrode 50 are stacked on the substrate 10 in parallel with a predetermined interval being formed therebetween. The semiconductor layer 60 fills the gap between the source electrode 40 and the drain electrode 50, and is stacked on the substrate 10, the source electrode 40 and the drain electrode 50. On the semiconductor layer 60, the insulator layer 30 is stacked, and the gate electrode 20 is stacked on the insulator layer 30.

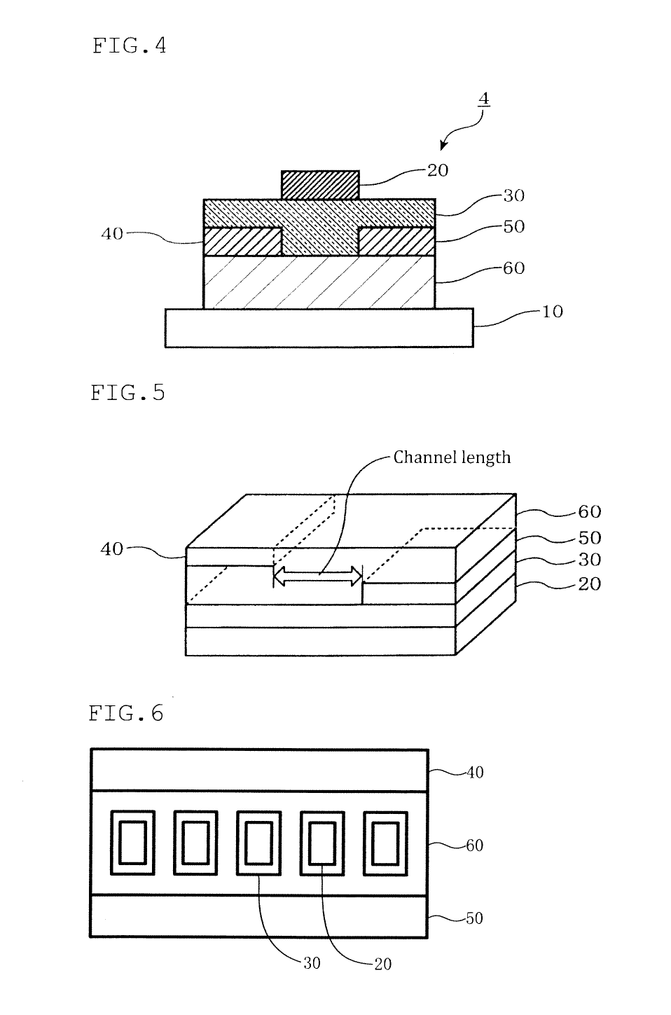

FIG. 4 is a view showing another configuration of the thin film transistor of the invention.

In a thin film transistor 4, the semiconductor layer 60 is stacked on the substrate 10, and on the semiconductor layer 60, the source electrode 40 and the drain electrode 50 are stacked in parallel with a predetermined interval being formed therebetween. The insulator layer 30 is stacked on the source electrode 40, the drain electrode 50 and the semiconductor layer 60, while filling the gap between the source electrode 40 and the drain electrode 50. The gate electrode 20 is stacked on the insulator layer 30.

The thin film transistor of the invention has an organic semiconductor layer (organic compound layer) or an inorganic semiconductor layer, a source electrode and a drain electrode formed such that they are opposed to each other with a predetermined interval being formed therebetween and a gate electrode formed with a predetermined interval from the source electrode and the drain electrode, and in which current flowing between the source electrode and the drain electrode is controlled by applying a voltage to the gate electrode.

No specific restrictions are imposed on the thin film transistor of the invention as long as it has a mechanism which allows it to conduct an on-off operation and to exhibit effects such as amplification by control of current flowing between the source electrode and the drain electrode by a voltage applied to the gate electrode, and the configuration of the thin film transistor is not restricted to the above-mentioned device configuration.

For example, the organic thin film transistor according to the invention may have the device configuration of a top and bottom contact organic thin film transistor (see FIG. 5) proposed by Yoshida et al. (National Institute of Advanced Industrial Science and Technology) (see The Proceedings of the Meeting of the Japan Society of Applied Physics and Related Societies, 49th Spring Meeting, 27a-M-3 (March 2002), or the device configuration of a vertical organic thin film transistor (see FIG. 6) proposed by Kudo et al. (Chiba University) (see Transactions of the Institute of Electrical Engineers of Japan, 118-A (1998), p. 1440).

Each constituent member of the organic thin film transistor of the invention is described below.

The insulator layer of the thin film transistor of the invention is a thin film obtained by polymerizing the composition of the invention.

It is preferred that the film thickness of the insulator layer be as small as possible in order to reduce the driving voltage of the thin film transistor. However, since the leakage current between the source electrode and the gate electrode is increased as the film thickness of the insulator layer is decreased, an appropriate film thickness is required to be selected. The thickness of the insulator layer is normally 10 nm to 5 μm, preferably 50 nm to 2 μm, and further preferably 100 nm to 1 μm.

The insulator layer is formed by forming the composition of the invention into a film by a coating method or a printing method such as the dipping method, the spin coating method, the casting method, the bar coating method, the roll coating method, the spray coating method, the blade coating method, the dip coating method, the die coating method, the flexo printing method, the off-set printing method, the gravure printing method, the screen printing method, the inkjet printing method or the like, followed by cross-linking polymerization by light or heat. In addition, the insulator layer may be stacked by combination of these methods.

The insulator layer may be formed only of a thin film obtained by polymerization of the composition of the invention. Further, it may be a stacked body of two or more layers including an insulator layer formed of other materials. Even if the insulator layer is formed only of a thin film obtained by polymerizing the composition of the invention, due to its high insulating properties, a high-performance thin film transistor can be fabricated by allowing it to have a sufficiently small film thickness. Further, it is possible to allow the thin film transistor of the invention to have a higher performance by combined use with other insulator layers.

As the material for forming the second insulator layer to be combined with a thin film obtained by polymerizing the composition of the invention, a material having a resistivity of 10 Ωcm or more at room temperature (20 to 25° C., for example) such as a metal oxide (including an oxide of silicon), a metal nitride (including a nitride of silicon), a polymer, an organic low-molecular material or the like can be used. In particular, a material having a dielectric constant higher than 3 is preferable.

As the metal oxide, the metal nitride or the like forming the second insulator layer, silicon oxide, aluminum oxide, tantalum oxide and titanium oxide can be given, for example.

An inorganic nitride such as silicon nitride (Si₃N₄, SiₓN_{y}, SiONₓ (x, y>0)) or aluminum nitride may also preferably be used. By forming the insulator layer using silicon nitride such as Si₃N₄, SiₓN_{y}, SiONₓ (x, y>0), charges may be induced on the insulating film more easily, whereby the threshold voltage of the transistor operation can be further reduced.

The second insulator layer may be formed using a precursor that includes a metal alkoxide.

The metal that forms the metal alkoxide is selected from transition metals, lanthanoids, and main-group elements, for example. Specific examples of the metal that forms the metal alkoxide include barium (Ba), strontium (Sr), titanium (Ti), bismuth (Si), tantalum (Ta), zirconium (Zr), iron (Fe), nickel (Ni), manganese (Mn), lead (Pb), lanthanum (La), lithium (Li), sodium (Na), potassium (K), rubidium (Rb), cesium (Cs), francium (Fr), beryllium (Be), magnesium (Mg), calcium (Ca), niobium (Nb), thallium (TI), mercury (Hg), copper (Cu), cobalt (Co), rhodium (Rh), scandium (Sc), yttrium (Y), and the like.

Examples of the alkoxide that forms the metal alkoxide include alkoxides derived from alcohols such as methanol, ethanol, propanol, isopropanol, butanol, and isobutanol and alkoxyalcohols such as methoxyethanol, ethoxyethanol, propoxyethanol, butoxyethanol, pentoxyethanol, heptoxyethanol, methoxypropanol, ethoxypropanol, propoxypropanol, butoxypropanol, pentoxypropanol and heptoxypropanol.

The second insulator layer may be formed using an organic compound as long as the object of the invention is not impaired.

Examples of the organic compound include a polyimide, a polyamide, a polyester, a polyacrylate, a photocurable resin that undergoes photoradical polymerization or photocationic polymerization, a copolymer that includes an acrylonitrile component, polyvinylphenol, polyvinyl alcohol, a novolac resin, cyanoethyl pullulan or the like.

In addition to the above-mentioned organic compound, the second insulator layer may also be formed using a polymer material having a high dielectric constant, such as polyethylene, polychloroprene, polyethylene terephthalate, polyoxymethylene, polyvinyl chloride, polyvinylidene fluoride, polysulphone, poly(methyl methacrylate) (PMMA), polycarbonate (PC), polystyrene (PS), polyacrylamide, poly(acrylic acid), a resol resin, polyxylylene, an epoxy resin, or the like.

The second insulator layer may be a mixture layer that is formed using a plurality of inorganic or organic compound materials mentioned above, or may be a multilayer stack of a layer formed singly of these materials.

The second insulator layer may further comprise an anodic oxidation film. The anodic oxidation film is formed by anodizing an anodizable metal using a known method. It is preferred that the anodic oxide film be further subjected to a sealing treatment.

Examples of the anodizable metal include aluminum and tantalum.

The anodizing method is not particularly limited, and may be implemented by a known method. An oxidation coating is formed by anodizing. An electrolyte solution used for anodizing is not particularly limited as long as a porous oxidation coating can be formed. Sulfuric acid, phosphoric acid, boric acid, a mixed acid of two or more of these acids, or a salt thereof is normally used as the electrolyte solution.

When the thickness of the second insulator layer is small, the root-mean-square voltage applied to the organic semiconductor increases, and the driving voltage and the threshold voltage of the device can be reduced. On the other hand, a source-gate leakage current increases when the thickness of the insulator layer is small. Therefore, it is necessary to appropriately select the thickness of the second insulator layer. The appropriate thickness of the second insulator layer is 10 nm to 5 μm.

No specific restrictions are imposed on the method for forming the second insulator layer, and vapor phase deposition and liquid phase deposition may be used. For example, vapor phase deposition such as vacuum deposition, molecular beam epitaxy, ion cluster beam technique, low-energy ion beam technique, ion plating, CVD, sputtering, or atmospheric pressure plasma method; and liquid phase deposition such as spray coating, spin coating, blade coating, dip coating, casting, roll coating, bar coating, or die coating, printing and inkjet can be used according to the type of the material.

The substrate serves to support the thin film transistor structure. As the material thereof, in addition to glass, an inorganic compound such as a metal oxide or a metal nitride, a plastic film (polyethylene terephthalate, polyethylene naphthalate, polyimide, polyethylene, polypropylene, polyether ether ketone, polysulfone, polyphenylene sulfide, polyether sulfone, polycarbonate, for example), a metal, a composite thereof, a laminate thereof, or the like may be used as the substrate. The substrate may not be used when the organic thin film transistor structure can be sufficiently supported by an element other than the substrate.

A silicon (Si) wafer is normally used as the substrate. In this case, the Si wafer may be used as the gate electrode and the substrate.

No particular restrictions are imposed on the semiconductor used in the semiconductor layer. For example, when an organic semiconductor layer is formed by using an organic semiconductor, an organic semiconductor material or the like stated in Chemical Review, vol. 107, page 1066 (2007) can be used.

The organic semiconductor layer may be a layer formed of a mixture obtained by combining a plurality of materials selected from the above-mentioned organic semiconductor materials or a stacked body of layers each being formed of one of these materials.

Specific examples of the material for the organic semiconductor layer include, though not limited thereto, a low-molecular weight material such as pentacene, naphthacene, anthracene, heptacene, hexacene, C60, C70, phenanthrene, pyrene, chrysene, perylene, coronene, rubrene, phthalocyanines and porphyrins and a derivative thereof; an oligomer such as di(styryl)benzene, oligoacetylene, oligothiophene and oligoselenophene and a derivative thereof; and a π-conjugated polymer such as polyacetylene, polythiophene, poly(3-hexylthiophene), poly(9,9-dioctylfluorene-co-bithiophene), polyphenylene vinylene and polythienylene vinylene and a derivative thereof or the like.

An inorganic semiconductor may be used as a semiconductor layer. Examples of the inorganic semiconductor layer include, not limited thereto, a non-monocrystalline semiconductor film or crystalline silicon represented by amorphous silicon, polycrystalline silicon, microcrystalline (microcrystal) silicon, further a compound semiconductor or oxide semiconductors, such as ZnO, a-InGaZnO, SiGe and GaAs.

Although the thickness of the semiconductor layer is not particularly restricted, it is normally 0.5 nm to 1 μm, preferably 2 nm to 250 nm.

The forming method used when forming the organic semiconductor layer is not particularly limited. A known forming method may be used.

For example, in the case of the device configuration of the organic thin film transistors 1 and 2 shown in FIG. 1 and FIG. 2, an organic semiconductor layer is desirably formed continuously after the formation of an insulator layer. The organic semiconductor layer may be formed by vapor phase deposition such as molecular beam epitaxy (MBE), vacuum deposition, chemical vapor deposition, molecular beam deposition and sputtering. It is also desired that an organic semiconductor layer be formed by a method in which a coating layer is formed by a coating/printing method such as a dipping method in which a solution obtained by dissolving a material in a solvent is dipped, spin coating, casting, bar coating, roll coating, spray coating, blade coating, dip coating, die coating, flexo printing, offset printing, gravure printing, screen printing and inkjet printing, and the coating layer is then subjected to baking, electropolymerization and self-assembly from a solution, or a combination thereof.

The organic semiconductor layer may be formed by combination of two or more of the above-mentioned film formation methods.

Since the field-effect mobility can be improved by improving the crystallinity of the semiconductor layer, it is preferable to keep the substrate temperature high during the film formation if the formation of the organic semiconductor layer is conducted by vapor phase deposition (deposition, sputtering or the like). It is preferable to anneal the film after the formation regardless of the film-forming method in order to increase the grain size of the crystals. The annealing temperature is preferably 50 to 200° C. The annealing time is preferably 10 minutes to 12 hours.

The material for forming the gate electrode, the source electrode, and the drain electrode is not particularly limited as long as the material is a conductive material. Examples of the material for forming the gate electrode, the source electrode, and the drain electrode include platinum, gold, silver, nickel, chromium, copper, iron, tin, antimony, tantalum, indium, palladium, tellurium, rhenium, iridium, aluminum, ruthenium, germanium, molybdenum, tungsten, antimony tin oxide, indium tin oxide (ITO), fluorine-doped zinc oxide, zinc, carbon, graphite, glassy carbon, a silver paste, a carbon paste, lithium, beryllium, sodium, magnesium, potassium, calcium, scandium, titanium, manganese, zirconium, gallium, niobium, a sodium-potassium alloy, a magnesium/copper mixture, a magnesium/silver mixture, a magnesium/aluminum mixture, a magnesium/indium mixture, an aluminum/aluminum oxide mixture, a lithium/aluminum mixture, and the like.

The thickness of each of the gate electrode, the source electrode and the drain electrode is not particularly limited as long as a current flows through the electrode, but is preferably 0.2 nm to 10 μm, and more preferably 4 to 300 nm. When the thickness of the electrode is within the above preferable range, it is possible to prevent a situation in which a voltage drop occurs due to an increase in resistance caused by a small thickness. Because of the small thickness, it is also possible to form a film within a short time, and smoothly form a stacked film due to the absence of a difference in level when stacking an additional layer such as a protective layer or an organic semiconductor layer.

The source electrode and the drain electrode are stacked with a predetermined interval, for example. The interval is determined according to the application of a thin film transistor, and is normally 0.1 μm to 1 mm, preferably 0.5 μm to 100 μm and further preferably 1 μm to 50 μm.

The source electrode and the drain electrode may be formed using a fluid electrode material (e.g., solution, paste, ink, or dispersion) that includes the above conductive material. It is preferable to form the source electrode and the gate electrode using a fluid electrode material that includes a conductive polymer or metal particles that include platinum, gold, silver, or copper.

As the solvent or dispersion medium for the above-mentioned fluid electrode material, it is preferable to use a solvent or a dispersion medium having a water content of 60 mass % or more (preferably 90 mass % or more) in order to suppress damage to the organic semiconductor.

A known conductive paste or the like may be used as the dispersion that includes fine metal particles. It is preferable that the dispersion include fine metal particles having a particle size of 0.5 to 50 nm or 1 to 10 nm. Examples of a material for forming the fine metal particles include platinum, gold, silver, nickel, chromium, copper, iron, tin, antimony, lead, tantalum, indium, palladium, tellurium, rhenium, iridium, aluminum, ruthenium, germanium, molybdenum, tungsten, zinc or the like.

It is preferable to form the electrode using a dispersion prepared by dispersing the fine metal particles in a dispersion medium (e.g., water or arbitrary organic solvent) using a dispersion stabilizer which is mainly formed of an organic material.

The fine metal particle dispersion may be prepared by a physical method (e.g., gas evaporation method, sputtering method, or metal vapor synthesis method) or a chemical method (e.g., colloidal method or co-precipitation method) that reduces metal ions in a liquid phase to produce metal particles. It is preferable to prepare the fine metal particle dispersion produced by the gas evaporation method.

Formation of an electrode by using fine metal particles is specifically conducted as follows. After drying the solvent of the fine metal dispersion, if needed, the dispersion is then heated at 100 to 300° C. in a pattern to thermally bond the metal particles, whereby an electrode pattern having an intended pattern can be formed.

It is preferable to form the source electrode and the drain electrode using a material that exhibits low electrical resistance at the contact surface with the organic semiconductor layer. The electrical resistance of the material corresponds to the field-effect mobility when producing a current control device, and must be as low as possible in order to obtain high mobility. This normally depends on the magnitude relationship between the work function of the electrode material and the energy level of the organic semiconductor layer.

When the work function (W) of the electrode material is referred to as “a”, the ionization potential (Ip) of the organic semiconductor layer is referred to as “b”, and the electron affinity (Af) of the organic semiconductor layer is referred to as “c”, it is preferable that the following relational expression be satisfied. Note that a, b, and c are positive values based on the vacuum level.

When producing a p-type organic thin film transistor, it is preferable that “b-a<1.5 eV” (expression (A)) (more preferably “b-a<1.0 eV”) be satisfied. A high-performance device can be obtained when the above relationship with the organic semiconductor layer can be maintained. It is preferable to select an electrode material having as large a work function as possible. It is preferable to use an electrode material having a work function of 4.0 eV or more, and more preferably 4.2 eV or more.

A metal having a large work function may be selected from the metals having a work function of 4.0 eV or more listed in Kagaku Binran (Handbook of Chemistry) Kiso-hen II (revised 3rd Edition, edited by the Chemical Society of Japan, Maruzen Co., Ltd., 1983, p. 493), for example.

Examples of a metal having a large work function include Ag (4.26, 4.52, 4.64, 4.74 eV), Al (4.06, 4.24, 4.41 eV), Au (5.1, 5.37, 5.47 eV), Be (4.98 eV), Bi (4.34 eV), Cd (4.08 eV), Co (5.0 eV), Cu (4.65 eV), Fe (4.5, 4.67, 4.81 eV), Ga (4.3 eV), Hg (4.4 eV), Ir (5.42, 5.76 eV), Mn (4.1 eV), Mo (4.53, 4.55, 4.95 eV), Nb (4.02, 4.36, 4.87 eV), Ni (5.04, 5.22, 5.35 eV), Os (5.93 eV), Pb (4.25 eV), Pt (5.64 eV), Pd (5.55 eV), Re (4.72 eV), Ru (4.71 eV), Sb (4.55, 4.7 eV), Sn (4.42 eV), Ta (4.0, 4.15, 4.8 eV), Ti (4.33 eV), V (4.3 eV), W (4.47, 4.63, 5.25 eV), Zr (4.05 eV), and the like. Among these, noble metals (Ag, Au, Cu, and Pt), Ni, Co, Os, Fe, Ga, Ir, Mn, Mo, Pd, Re, Ru, V, and W are preferable.

In addition to the metal, ITO, carbon materials such as carbon black, fullerene and carbon nanotube and a conductive polymer such as polyaniline and PEDOT:PSS are preferable. The electrode material may include only one type of these materials having a large work function, or may include two or more types of these materials having a large work function, as long as the work function of the electrode material satisfies the expression (A).

When producing an n-type organic thin film transistor, it is preferable that “a-c<1.5 eV” (expression (B)) (more preferably “a-c<1.0 eV”) be satisfied. A high-performance device can be obtained when the above relationship with the organic semiconductor layer can be maintained. It is preferable to select an electrode material having as small a work function as possible. It is preferable to use an electrode material having a work function of 4.3 eV or less, and more preferably 3.7 eV or less.

A metal having a small work function may be selected from the metals having a work function of 4.3 eV or less listed in Kagaku Binran (Handbook of Chemistry) Kiso-hen II (revised 3rd Edition, edited by the Chemical Society of Japan, Maruzen Co., Ltd., 1983, p. 493), for example.

Examples of a metal having a small work function include Ag (4.26 eV), Al (4.06, 4.28 eV), Ba (2.52 eV), Ca (2.9 eV), Ce (2.9 eV), Cs (1.95 eV), Er (2.97 eV), Eu (2.5 eV), Gd (3.1 eV), Hf (3.9 eV), In (4.09 eV), K (2.28 eV), La (3.5 eV), Li (2.93 eV), Mg (3.66 eV), Na (2.36 eV), Nd (3.2 eV), Rb (4.25 eV), Sc (3.5 eV), Sm (2.7 eV), Ta (4.0, 4.15 eV), Y (3.1 eV), Yb (2.6 eV), Zn (3.63 eV), and the like. Among these, Ba, Ca, Cs, Er, Eu, Gd, Hf, K, La, Li, Mg, Na, Nd, Rb, Y, Yb, and Zn are preferable.

The electrode material may include only one type of these materials having a small work function, or may include two or more types of these materials having a small work function, as long as the work function of the electrode material satisfies the expression (B). Since a metal having a small work function easily deteriorates upon contact with moisture or oxygen in air, it is desirable to optionally coat a metal having a small work function with a metal that is stable in air (e.g., Ag or Au). The thickness of the coating must be 10 nm or more, and a metal having a small work function can be effectively protected from oxygen and moisture as the thickness of the coating increases. It is desirable to set the thickness of the coating to 1 μm or less from the viewpoint of productivity and the like.

The source electrode and the drain electrode may be formed by deposition, electron beam deposition, sputtering, an atmospheric pressure plasma method, ion plating, chemical vapor deposition, electrodeposition, electroless plating, spin coating, printing, an inkjet method, or the like. The electrode may optionally be patterned by a method that subjects a conductive thin film formed by the above method to a known photolithographic technique or a lift-off technique to form an electrode, a method that forms a resist on a metal foil (e.g., aluminum foil or copper foil) by a thermal transfer method, an inkjet method, or the like, and etches the metal foil, or the like.

As mentioned above, the source electrode and the drain electrode may be formed by patterning directly by the inkjet method a solution or a dispersion of a conductive polymer, or a dispersion containing fine metal particles, or may be formed from a coating film by lithography, laser ablation, or the like. An electrode pattern may also be formed by patterning of conductive ink, conductive paste or the like containing a conductive polymer or fine metal particles using a printing method such as relief printing, intaglio printing, planographic printing, or screen printing.

In addition to the above-mentioned electrode materials, as the electrode material for the gate electrode, the source electrode and the drain electrode, it is preferable to use a known conductive polymer of which the conductivity is increased by doping or the like. For example, conductive polyaniline, conductive polypyrrole, conductive polythiophene (a complex of polyethylenedioxythiophene and polystyrenesulfonic acid or the like) may preferably be used. The contact resistance of the source electrode and the drain electrode with the semiconductor layer can be reduced by utilizing these materials.

The thin film transistor according to the invention may include a buffer layer between the semiconductor layer, and the source electrode and the drain electrode in order to improve the injection efficiency, for example.

It is desirable to form the buffer layer of an n-type organic thin film transistor using a compound that is used to form a cathode of an organic electroluminescence device and has an alkali metal ionic bond or an alkaline-earth metal ionic bond such as LiF, Li₂O, CsF, Na₂CO₃, KCl, MgF₂, or CaCO₃.

It is desirable to form the buffer layer of a p-type organic thin film transistor using FeCl₃, a cyano compound such as TCNQ, F₄-TCNQ and HAT, CFₓ, a metal oxide other than alkali metal/alkaline-earth metal oxides such as GeO₂, SiO₂, MoO₃, V₂O₅, VO₂, V₂O₃, MnO, Mn₃O₄, ZrO₂, WO₃, TiO₂, In₂O₃, ZnO, NiO, HfO₂, Ta₂O₅, ReO₃, and PbO₂, or an inorganic compound such as ZnS and ZnSe. These oxides tend to show oxygen deficiency that is suitable for hole injection. The buffer layer may also be formed using a compound that is used to form a hole-injecting layer and a hole-transporting layer of an organic EL device (e.g., amine compound such as TPD and NPD or CuPc). It is also desirable to form the buffer layer using two or more compounds among these compounds.

In the thin film transistor of the invention, a gas barrier layer may be formed on the entire or part of the outer circumferential surface of the organic transistor device in consideration of the influence of oxygen, water, and the like contained in air on the organic semiconductor layer.

The gas barrier layer may be formed using a known material. For example, the gas barrier layer may be formed using polyvinyl alcohol, an ethylene-vinyl alcohol copolymer, polyvinyl chloride, polyvinylidene chloride, polychlorotrifluoroethylene, or the like. An organic material or an inorganic material having insulating properties exemplified above as the material for an insulator layer may also be used.

### EXAMPLES

### Example 1

0.4 g of 1,3-adamantane dimethanol diacrylate represented by the following structural formula (compound (1)) (a colorless transparent liquid manufactured by Idemitsu Kosan, Co., Ltd.), 0.04 g of benzoin isobutyl ether as a polymerization initiator and 4 g of MEK as a solvent were mixed, whereby a composition for forming an insulating material (film) having a solid concentration of 10 mass % was obtained.

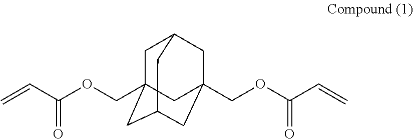 [SMILES: C=CC(=O)OCC12CC3CC(C1)CC(COC(=O)C=C)(C3)C2]

On a 25×20×1.1 mm glass substrate, an ITO film was formed in a thickness of 100 nm. This film was patterned by using the photolithographic method to form a transparent gate electrode (hereinbelow, a substrate provided with an ITO film is referred to as a transparent supporting substrate). This transparent supporting substrate was subjected to ultrasonic cleaning with isopropyl alcohol for 5 minutes, and then washed with pure water for 5 minutes. Further, the substrate was subjected to ultrasonic cleaning with isopropyl alcohol for 5 minutes, and dried by blowing of N₂ gas for drying. Finally, the substrate was washed for 5 minutes in a UV ozone washing apparatus (manufactured by SEN lights Co., Ltd.).

The composition for forming an insulating material (film) thus prepared was filtered by means of a PTFE membrane filter having a pore size of 0.2 microns, and then added dropwise on the above-mentioned transparent supporting substrate in the nitrogen atmosphere. The substrate was subjected to spin coating at 2000 rpm for 30 seconds. Thereafter, the composition was exposed to UV light having a wavelength of 365 nm and cross-linked, whereby a gate insulator layer having a film thickness of 400 nm was formed. Under the same conditions, insulator layers were formed on a plurality of substrates, and evaluation of the insulator layers and fabrication of an organic thin film transistor were conducted as follows.

In the Examples and the Comparative Examples, the thickness of the insulator layer was measured by means of a SURF CODER (ET 3000, a fine shape measuring machine manufactured by Kosaka Laboratory Ltd.).

### [Evaluation of Insulator Layer]

For the insulator layer prepared as mentioned above, the following measurements were conducted. The results are shown in Table 1.

### (Resistance to Solvents)

On the substrate on which the insulator layer was formed, toluene as a common solvent was added dropwise, and spin coating was conducted at 3000 rpm for 30 seconds. This operation was repeated twice, whereby no-load spin coating was conducted. Thereafter, the thickness of the insulator layer was measured by means of a contact-type thickness meter. By comparing the thickness of the insulator layer before and after the no-load spinning, the resistance to the solvent was evaluated.

The resistance to the solvent (%) was obtained by the following formula:

(Thickness after no-load spinning)/(Thickness before no-load spinning)×100

### (Leakage Current Density)

By using the deposition method, a gold electrode (thickness: 50 nm) was formed on the insulator layer through a metal mask such that the gold electrode was opposed to the ITO electrode with the insulator layer being therebetween. An electric field of 2 MV/cm was applied between the electrodes, the current density flowing vertically in the insulator layer was measured. This current density was evaluated as the leakage current density. Application of the voltage and measurement of the current were conducted by using a semiconductor performance evaluation system (4200SCS, manufactured by Keithley Instruments, Co., Ltd.).

### [Production of Organic Thin Film Transistor]

On the substrate on which the insulator layer was formed as mentioned above, a 50 nm-thick pentacene thin film (semiconductor layer) was formed by means of a vacuum deposition apparatus at a deposition rate of 0.05 nm/s. Then, by forming gold into a thickness of 50 nm through a metal mask, a source electrode and a drain electrode which did not contact with each other were formed such that the interval therebetween (channel length: L) became 50 μm. At the time, film formation was conducted such that the width of the source electrode and the drain electrode (channel width: W) became 1 mm, whereby a thin film transistor having a configuration shown in FIG. 2 was fabricated.

To a gate electrode of the resulting thin film transistor, a gate voltage of 0 to −25V was applied, and a voltage of 5 to −25V was applied between the source electrode and the drain electrode to allow electric current to flow. Then, the threshold voltage (Vth) and the filed effect mobility p were evaluated. Application of each voltage and measurement of the current flowing between the source electrode and the drain electrode were conducted by using a semiconductor performance evaluation system (4200SCS, manufactured by Keithley Instruments, Co., Ltd.).

The field effect mobility p was calculated by the following formula (A):

I_{D}=(W/2L)·C·μ·(V_{G}−V_{T})² (A)

wherein I_{D} is a source-drain current, W is a channel width, L is a channel length, C is an electric capacity per unit area of the gate insulator layer, V_{T} is a gate threshold voltage and V_{G} is a gate electrode.

As a result, the threshold voltage in the current saturation region was −10.1V and the field effect mobility p was 4.5×10⁻² cm²/Vs. The results are shown in Table 2.

In the resulting thin film transistor, holes are induced in the channel region (source-drain) of the organic semiconductor layer and the transistor was operated as a p-type transistor.

### Example 2

An insulator layer was formed in the same manner as in Example 1, except that the composition containing the following compound (2) was used instead of the compound (1), and the insulator layer was evaluated in the same manner as in Example 1. The compound (2) was produced by the method stated in Examples 1 and 2 of WO2007/020901. The results are shown in Table 1. Further, a thin film transistor was fabricated and evaluated in the same manner as in Example 1. The results are shown in Table 2.

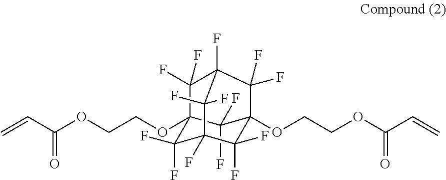 [SMILES: C=CC(=O)OCCOC12C(F)(F)C3(F)C(F)(F)C(F)(C1(F)F)C(F)(F)C(OCCOC(=O)C=C)(C3(F)F)C2(F)F]

### Example 3

An insulator layer was formed in the same manner as in Example 1, except that the composition containing the following compound (3) (a reagent manufactured by Sigma-Aldrich) instead of the compound (1), and the insulator layer was evaluated in the same manner as in Example 1. The results are shown in Table 1.

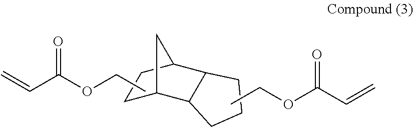

### Example 4

An insulator layer was formed in the same manner as in Example 1, except that the composition obtained by mixing the compound (2) and the compound (3) at an amount ratio of 50 wt %:50 wt % was used instead of the compound (1), and the insulator layer was evaluated in the same manner as in Example 1. The results are shown in Table 1.

### Example 5

An insulator layer was formed in the same manner as in Example 1, except that the composition obtained by mixing the compound (3) and the following compound (4) (a reagent manufactured by Sigma-Aldrich) at an amount ratio of 50 wt %:50 wt % was used instead of the compound (1), and the insulator layer was evaluated in the same manner as in Example 1. The results are shown in Tablet

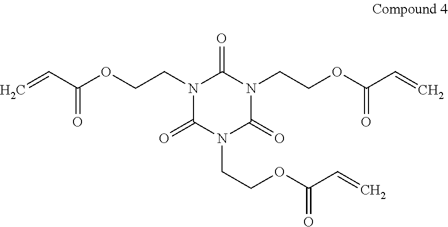 [SMILES: C=CC(=O)OCCn1c(=O)n(CCOC(=O)C=C)c(=O)n(CCOC(=O)C=C)c1=O]

### Example 6

An insulator layer was formed in the same manner as in Example 1, except that the composition obtained by mixing the compound (3) and the following compound (5) (a reagent manufactured by Sigma-Aldrich) at an amount ratio of 50 wt %:50 wt % was used instead of the compound (1), and the insulator layer was evaluated in the same manner as in Example 1. The results are shown in Table 1.

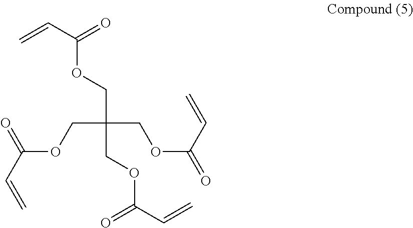 [SMILES: C=CC(=O)OCC(COC(=O)C=C)(COC(=O)C=C)COC(=O)C=C]

### Comparative Example 1

An insulator layer was formed in the same manner as in Example 1, except that a composition comprising poly(methyl methacrylate) (PMMA) was used instead of the compound (1), and the insulator layer was evaluated in the same manner as in Example 1. The results are shown in Table 1.

TABLE 1

Insulator layer

| | Resistance to | Leakage current density |
|---|---|---|
| | solvent [%] | [A/cm²] |
| Example 1 | 97 | 6.0 × 10⁻⁹ |
| Example 2 | 99 | 6.3 × 10⁻⁹ |
| Example 3 | 97 | 5.8 × 10⁻⁹ |
| Example 4 | 100 | 1.1 × 10⁻⁹ |
| Example 5 | 100 | 3.4 × 10⁻⁹ |
| Example 6 | 99 | 4.2 × 10⁻⁹ |
| Com. Ex. 1 | 69 | 9.0 × 10−9 |

TABLE 2

| | |
|---|---|
| Semiconductor | FET properties |

| | material | Mobility [cm²/Vs] | Vth [V] |
|---|---|---|---|
| Example 1 | Pentacene | 4.5 × 10⁻² | −10.1 |
| Example 2 | Pentacene | 3.7 × 10⁻² | −6.3 |
| Example 3 | Pentacene | 6.6 × 10⁻² | −12.5 |
| Example 4 | Pentacene | 1.1 × 10⁻¹ | −5.1 |
| Example 5 | Pentacene | 8.1 × 10⁻² | −9.0 |
| Example 6 | Pentacene | 3.7 × 10⁻² | −4.7 |

As is understood from Table 1, it was confirmed that a thin film obtained by subjecting to cross-linking polymerization the composition containing the compounds (1) to (3) as polymerizable components had resistance to solvent and had small leakage current density. Further, it was confirmed that a thin film transistor containing a thin film obtained by polymerizing the composition containing the compounds (1) to (3) as main polymerizable components in the insulator layer exhibited excellent performance when applied in the field of electronic paper, liquid crystal displays, organic EL displays or the like.

### Example 7

A composition for forming an insulating material was prepared using the compound (1) in the same manner as in Example 1, except that the MEK as the solvent was not used. Further, the composition was placed in a vial bottle and exposed to UV rays to allow it to be cross-linked, whereby an insulating material was formed. By using this insulating material, the following heat resistance test was conducted. The results are shown in Table 3.

### (Glass Transition Temperature: Tg)

5 mg of the insulating material was placed in an aluminum container, and the temperature thereof was elevated from 0° C. at a rate of 10° C./min by means of a differential scanning calorimeter (manufactured by Perkinelmer Co., Ltd.) and the glass transition temperature was obtained from a break point observed in the resulting heat reflux curve.

### (1% Mass Decrease Temperature: Td1)

By using a TG-DTA apparatus (TG/DTA6200 manufactured by Seiko Instruments, Inc.), 10 mg of the above-obtained insulating material was heated at a rate of 10° C./min in the nitrogen atmosphere, whereby a temperature at which the weight was reduced by 1% (Td1) was measured.

Table 3 shows either Tg or Td1, which is lower.

### Comparative Example 2

An insulating material was prepared in the same manner as in Example 7, except that a composition containing poly(methyl methacrylate) (PMMA) was used instead of the compound (1), and the insulating material was subjected to a heat resistance test. The results are shown in Table 3.

TABLE 3

| | Tg or Td1 [° C.] |
|---|---|
| Example 7 | 366 (Td1) |
| Com. Ex. 2 | 108 (Tg) |

From Table 3, it can be understood that the thin film obtained by subjecting the composition containing the compound (1) as the polymerizable component to cross-linking polymerization had high heat resistance.

### INDUSTRIAL APPLICABILITY

The insulating material of the invention is effective as an insulating film for an electronic device such as a planarized film, a passivation film, an interlayer insulating film or a gate insulating film of a TFT. The insulating material of the invention is particularly effective as a gate insulating film of a TFT in which a low leakage current density directly contributes to the performance.

The thin film transistor of the invention can be preferably used in driving circuits of electronic paper, liquid crystal displays, organic EL displays or the like, various sensors, authentication tags or the like.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification are incorporated herein by reference in its entirety.

1. A composition for forming an insulating material used in electronic devices which comprises, as a polymerizable component, a monomer comprising two or more (meth)acrylic moieties and a polycyclic alicyclic structure.

2. The composition for forming an insulating material used in electronic devices according to claim 1, wherein the polycyclic alicyclic structure is an adamantane skeleton.

3. The composition for forming an insulating material used in electronic devices according to claim 1, wherein the polycyclic alicyclic structure is a tricyclo[5.2.1.0^{2,6}]decane skeleton.

4. The composition for forming an insulating material used in electronic devices according to claim 2, wherein the structure of the monomer is represented by the following formula (I) or (II): 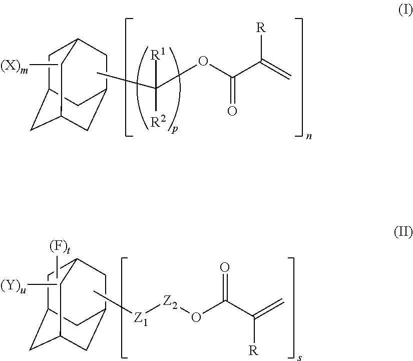
wherein R is a hydrogen atom, a fluorine atom, a methyl group or a trifluoromethyl group, X is a fluorine atom, a methyl group, a trifluoromethyl group or ═O formed by combination of two Xs; and Y is a methyl group or ═O formed by combination of two Ys; R¹ and R² are independently a hydrogen atom, a halogen atom or an alkyl group having 1 to 5 carbon atoms;
p is an integer of 0 to 6; m is an integer of 0 to 14; n is an integer of 2 or more; t is an integer of 0 to 14; u is an integer of 0 to 14; and s is an integer of 2 or more; and plural Xs and plural Ys may be the same or different from each other;
Z₁ is a group represented by —C_{(q+r)}F_{2q}H₂ᵣ— (q is an integer of 0 to 4 and r is an integer of 0 to 4); and Z₂ is a single bond or a group represented by the following formula (II-1) or (II-2): 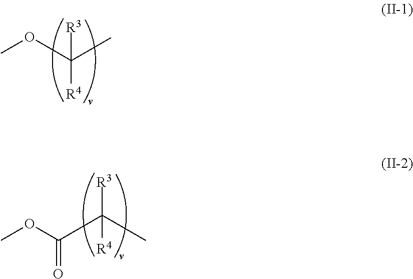
wherein R³ and R⁴ are independently a hydrogen atom, a halogen atom or an alkyl group having 1 to 5 carbon atoms; and v is an integer of 1 to 4.

5. The composition for forming an insulating material used in electronic devices according to claim 4, wherein in the formula (I) X is a methyl group, a trifluoromethyl group or ═O formed by combination of two Xs; and R¹ and R² are hydrogen atoms;
in the formula (II) wherein t is an integer of 6 to 14 and u is an integer of 0 to 9; and
in the formulas (II-1) and (II-2) wherein R³ and R⁴ are hydrogen atoms.

6. An insulating material used in electronic devices that is a polymer material obtained by curing the composition for forming an insulating material used in electronic devices according to claim 1.

7. An electronic device which uses the insulating material used in electronic devices according to claim 6 as a planarized film, a passivation film, an interlayer insulating film or a gate insulating film.

8. A thin film transistor comprising three terminals of a gate electrode, a source electrode and a drain electrode, an insulator layer and a semiconductor layer in which source-drain current is controlled by applying a voltage to the gate electrode, wherein the insulating material used in electronic devices according to claim 6 is used in the insulator layer.

9. The thin film transistor according to claim 8 wherein the semiconductor layer comprises an organic semiconductor.
